(19) United States
(12) Patent Application Publication
(10) Pub. No.: US 2026/0047428 A1
(43) Pub. Date: Feb. 12, 2026

(54) CHARGE COMPENSATION IN A SEMICONDUCTOR DEVICE

(71) Applicant: IDEAL SEMICONDUCTOR DEVICES, INC., Bethlehem, PA (US)

(72) Inventors: David Jauregui, Bethlehem, PA (US); John Manning Savidge Neilson, Norristown, PA (US)

(21) Appl. No.: 18/795,383

(22) Filed: Aug. 6, 2024

(51) Int. Cl. H01L 23/522; H01L 21/02; H01L 21/762; H01L 29/423; H01L 29/66; H01L 29/872

(52) U.S. Cl. CPC H01L 23/5228; H01L 21/02178; H01L 21/02181; H01L 21/76232; H10D 8/051; H10D 8/60; H10D 64/513

(57) ABSTRACT

A method for forming a charge balance region in a semiconductor device includes: providing an epitaxial layer on a substrate, whereby a diffusion layer is formed between the substrate and the epitaxial layer; forming a plurality of recessed features extending in a vertical direction in the epitaxial layer and laterally spaced apart from one another; forming an insulating layer on at least sidewalls of each of the recessed features; and forming a resistive film on the insulating layer and a bottom of each of the recessed features using atomic layer deposition. The resistive film is configured to provide a conductive path between an upper surface of the epitaxial layer and one of the diffusion layer, a lower portion of the epitaxial layer, or the substrate, whereby a current flowing through the resistive film fully depletes at least a portion of the epitaxial layer between adjacent recessed features.

### BACKGROUND

The present invention relates generally to electrical and electronic circuitry, and more particularly relates to semiconductor devices and the fabrication thereof.

Power semiconductor devices, including, but not limited to, lateral and vertical devices (e.g., metal-oxide-semiconductor field-effect transistors (MOSFETs), insulated gate bipolar transistors (IGBTs), and diodes), are well known in the art, as are the various applications in which such devices can be employed. Exemplary applications in which semiconductor devices are used include communications systems (e.g., radio frequency (RF) and microwave), automotive electronics, power supplies, high-voltage motors, etc.

Two important electrical parameters which are often used to characterize the performance of a semiconductor device, particularly power semiconductor devices, are breakdown voltage and on-state resistance, also referred to as on-resistance. Breakdown voltage, V_{BR}, is a parameter of a P-N junction (e.g., in a diode, transistor, etc.) that often defines the largest reverse voltage that can be applied without causing an exponential increase in current flowing through the junction, ultimately damaging the device. On-state resistance, R_{DSon}, of a field-effect transistor (FET) device generally refers to the internal resistance of the device when the device is in its fully conducting (i.e., “on”) state.

It is generally desirable for a power semiconductor device to have as high a breakdown voltage and as low an on-state resistance as possible. However, breakdown voltage and on-state resistance are mutually exclusive properties of a conventional semiconductor device, since increasing the breakdown voltage rating, for example by incorporating a thicker and lower doped body or drift region in the device, undesirably leads to higher on-state resistance. Conversely, increasing the doping density in the drift region to thereby reduce the on-state resistance undesirably leads to lower breakdown voltage in the device.

One way to assess the performance improvement of the relationship between on-state resistance and reverse blocking voltage of a semiconductor device is to multiply the reverse voltage breakdown (V_{BR}) rating with the on-state resistance per millimeter squared (RSP) as a figure of merit (FOM), which may be referred to as RSP·V_{BR} FOM.

One way to increase the doping of a drift region while maintaining a desired breakdown voltage is to charge compensate the drift region as part of the semiconductor device structure. Various known techniques have been implemented in an attempt to facilitate charge compensation in the drift region of a power semiconductor device, including the use of PN implanted columns or a metal field plate, to improve RSP·V_{BR} FOM. However, these conventional techniques have limitations, including, for example, significant cost of manufacture (e.g., at least twice the number of photolithographic mask steps) and limited voltage blocking range. For example, a PN implanted structure is generally only good for blocking voltages in a narrow range of about 500V to 800V. At lower voltages (e.g., below 500V), the cost to manufacture the device becomes prohibitive; at higher voltages (e.g., above 800V), on-state resistance R_{DSon} becomes worse. Conversely, a metal field plate structure is generally only good for blocking voltages in a narrow range of about 80V to 200V. At lower voltages (e.g., below 80V), the cost to manufacture the device becomes prohibitive; at higher voltages (e.g., above 200V), on-state resistance R_{DSon} becomes worse.

It is rare to find a solution that improves RSP·V_{BR} FOM while improving voltage blocking range and without increasing the cost of manufacture; three key elements of performance. Many known industry solutions may improve on one of the three key elements of performance while worsening the other two.

### SUMMARY

The present inventive concept, as manifested in one or more embodiments, beneficially provides a semiconductor device and a method of fabricating such a semiconductor device that improves RSP·V_{BR} FOM while reducing cost of manufacture and increasing voltage blocking range, thereby improving on all three key elements of performance in a power semiconductor device.

In accordance with an embodiment of the inventive concept, a method for forming a charge balance region in a semiconductor device includes: providing an epitaxial layer on an upper surface of a substrate, whereby a diffusion layer is formed between the substrate and the epitaxial layer; forming a plurality of recessed features extending in a vertical direction in the epitaxial layer and laterally spaced apart from one another; forming an insulating layer on at least sidewalls of each of the recessed features; and forming a resistive film on the insulating layer and a bottom of each of the recessed features using atomic layer deposition. The resistive film is configured to provide a conductive path between an upper surface of the epitaxial layer and the diffusion layer or a lower portion of the epitaxial layer, whereby a current flowing through the resistive film fully depletes at least a portion of the epitaxial layer between adjacent recessed features.

Embodiments of an illustrative method may comprise forming a Schottky diode, further including: at least partially filling each of the recessed features with a fill material, an upper surface of the fill material being substantially coplanar with the upper surface of the epitaxial layer; forming a Schottky contact in the epitaxial layer proximate the upper surface of the epitaxial layer; forming a first metal contact on an upper surface of the Schottky contact and extending in the second direction, the first metal contact serving as an anode of the Schottky diode; and forming a second metal contact on a back surface of the substrate and extending in the second direction, the second metal contact serving as a cathode of the Schottky diode.

Embodiments of an illustrative method may comprise forming a MOSFET device, further including: at least partially filling each of the recessed features with a fill material, an upper surface of the fill material being substantially coplanar with the upper surface of the epitaxial layer; forming a body region in the epitaxial layer proximate the upper surface of the epitaxial layer and between adjacent recessed features in the second direction, the body region extending partially in the epitaxial layer in the first direction, the body region having a first conductivity type and the epitaxial layer having a second conductivity type; forming a plurality of first wells in the body region proximate an upper surface of the body region and extending partially in the body region in the first direction, the first wells having the first conductivity type; forming a plurality of second wells in the body region proximate the upper surface of the body region and extending partially in the body region in the first direction, the second wells being adjacent the first wells in the second direction and having the second conductivity type; forming a trenched gate structure extending in the first direction from the upper surface of the body region, through the body region and into the epitaxial layer, the trenched gate structure being disposed between adjacent second wells in the second direction; forming a source electrode on an upper surface of the recessed features and electrically connected to the body region and the resistive film; and forming a drain electrode on a back surface of the substrate and electrically connected to the substrate.

In accordance with another embodiment of the invention, a semiconductor device includes: a diffusion layer on an upper surface of a substrate, the diffusion layer having a first doping concentration; an epitaxial layer on an upper surface of the diffusion layer, the epitaxial layer having a second doping concentration that is less than the first doping concentration; a plurality of recessed features extending in a first direction, perpendicular to the upper surface of the substrate, in the epitaxial layer and extending longitudinally in a second direction parallel to the upper surface of the substrate, the recessed features being spaced apart from one another in a third direction parallel to the upper surface of the substrate and intersecting the second direction; an insulating layer on at least sidewalls of each of the plurality of recessed features; and a resistive film on at least a portion of the insulating layer and a bottom of each of the plurality of recessed features, the insulating layer being disposed between the resistive film and the epitaxial layer. The resistive film is configured to provide a conductive path between an upper surface of the epitaxial layer and the diffusion layer or a lower portion of the epitaxial layer, whereby a current flowing through the resistive film fully depletes at least a portion of the epitaxial layer between adjacent recessed features to form a charge balance region in the semiconductor device.

As the term may be used herein, “facilitating” an action includes performing the action, making the action easier, helping to carry the action out, or causing the action to be performed. Thus, by way of example only and without limitation, in the context of a processor-implemented method, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Aspects of the present inventive concept can provide substantial beneficial technical effects. By way of example only and without limitation, techniques according to embodiments of the present disclosure may provide one or more of the following advantages, among other benefits:
provides charge compensation in a semiconductor device in a manner which improves a relationship between on-state resistance and reverse blocking voltage in the device while minimizing cost of manufacture and improving voltage blocking range;
provides charge compensation in the semiconductor device that is substantially independent of process variations, particularly with regard to charge carriers in a drift region of the device;
eliminates the need for using semi-insulating polysilicon (SIPOS) in the semiconductor fabrication process;
can be easily integrated with traditional complementary metal-oxide-semiconductor (CMOS) fabrication technologies;
minimizes additional process steps, thereby reducing overall cost and fabrication complexity and improving yield;
can be applied across a wide range of blocking voltages.

These and other features and advantages of the present invention will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a schematic cross-sectional view depicting at least a portion of an example semiconductor device including a charge balance region, according to one or more embodiments of the inventive concept;

FIGS. 2A-2D are schematic cross-sectional views depicting an enlarged region A of the example semiconductor device shown in FIG. 1 conceptually illustrating the formation of a depletion region in the epitaxial/drift layer of the device, according to one or more embodiments;

FIGS. 3A-3H are schematic cross-sectional views depicting intermediate processes in an illustrative method for fabricating a charge balanced semiconductor device, according to one or more embodiments of the inventive concept;

FIGS. 4A-4D are schematic cross-sectional views depicting alternative intermediate processes in an illustrative method for fabricating a charge balanced semiconductor device, according to one or more embodiments of the inventive concept;

FIGS. 5A-5F are schematic cross-sectional views depicting intermediate processes that may be optionally performed in an illustrative method for fabricating a charge balanced semiconductor device, according to one or more embodiments of the inventive concept;

FIGS. 6A and 6B are schematic cross-sectional views depicting intermediate processes that may be optionally performed in an illustrative method for fabricating a charge balanced semiconductor device, according to one or more embodiments of the inventive concept;

FIGS. 7 and 8 are schematic cross-sectional views depicting at least a portion of example semiconductor devices including recessed features formed at different depths, according to alternative embodiments of the inventive concept;

FIGS. 9A and 9B are schematic top plan views depicting at least a portion of example semiconductor devices conceptually illustrating different configurations of recessed features, according to embodiments of the inventive concept; and

FIG. 10 is a schematic cross-sectional view depicting at least a portion of an illustrative power MOSFET device that incorporates enhanced charge balancing, according to one or more embodiments of the present invention.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in one or more embodiments thereof, will be described herein in the context of an illustrative power semiconductor device including a charge compensation structure having an improved relationship between on-state resistance and reverse voltage blocking, and methods for fabricating such a device. The novel charge compensation structure according to embodiments of the invention may have beneficial application, for example, in a power device or power system environment for providing direct current (DC)-DC or alternating current (AC)-DC conversion. It is to be appreciated, however, that the present inventive concepts are not limited to the specific structure and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

Embodiments of the invention will be described herein in the context of illustrative semiconductor fabrication methods and devices which utilize atomic layer deposition (ALD) in the formation of a charge compensation structure in a semiconductor device. Specifically, in one or more embodiments, recessed features are formed in a drift region of the device, and one or more exposed surfaces (e.g., sidewalls and/or a bottom wall) of the recessed features are conformally coated with a film using ALD. The film may comprise a dielectric material (e.g., oxide) which, during thermal processing, becomes resistive proximate the sidewalls and/or bottom of the recessed features, according to one or more embodiments. As used herein, the term “and/or” includes any and all combinations of one or more of the associated listed items. The resistive film provides an electrical path between a lower and an upper surface of the device which, when the device is reverse-biased, will convey a current that depletes the drift region between adjacent recessed features. This allows the drift region to be more heavily doped to thereby reduce on-state resistance in the device without sacrificing reverse voltage blocking of the device. The term “film,” as may be used herein, is intended to broadly refer to a thin layer of material (regardless of its formation, such as being deposited, grown, etc.), and thus the terms “film” and “layer” may be used interchangeably herein.

It should be understood that embodiments of the invention are not limited to these or any other particular semiconductor fabrication method(s) and/or semiconductor devices. Rather, embodiments of the invention are more broadly applicable to techniques for beneficially creating a charge balance region in a semiconductor device. It should also be understood that the embodiments of the invention are not limited to a vertical power semiconductor device, rather embodiments of the invention are also applicable to, for example, other power devices, planar gate devices, lateral power devices, N-channel devices, P-channel devices, lateral semiconductor devices, insulated gate bipolar transistors (IGBTs), diodes, bipolar junction transistors (BJTs), enhancement mode devices, depletion mode devices, wide band gap (WGB) semiconductors (e.g., gallium nitride (GaN) or silicon carbide (SiC)), and the like. Similarly, the technology described herein is applicable to devices with either N-type substrate materials or P-type substrate materials. Accordingly, it will become apparent to those skilled in the art given the teachings herein that numerous modifications can be made to the illustrative embodiments shown that are within the scope of the claimed invention.

Various semiconductor fabrication techniques have been used in an attempt to increase breakdown voltage in a transistor device without significantly increasing on-resistance. Illustrative techniques for increasing breakdown voltage in a device include the use of exotic materials (e.g., silicon carbide and gallium nitride) in the semiconductor processing, which may be commercially prohibitive due primarily to cost, and using a super-junction structure. The super-junction structure, pioneered by Infineon Technologies based on U.S. Pat. No. 4,754,310 to David Coe (“Coe”), the disclosure of which is incorporated by reference herein, is one method of commercially fabricating high-voltage transistor devices.

As described in Coe, the super-junction concept involves using multiple N-type doped epitaxial layers grown with subsequent ion implantation of P-type material between epitaxial growth steps to form alternating columns of N-type and P-type material. The classic alternating columns of N-type and P-type material characteristic of a super-junction device results in a two-dimensional field. A common method of manufacturing a charge balance region involves the growth of multiple epitaxial layers followed by ion implantation to form alternating columns of N-type and P-type material (commonly referred to as a multiple-layer epitaxial growth, or multi-epi, implant method). Specifically, a drift layer of the device is formed having a plurality of alternating N-type pillars and P-type pillars. By interleaving high aspect ratio regions of N and P layers, a space charge formed in these regions by depletion is substantially balanced and does not exceed a critical value for avalanche breakdown. When compared with a conventional N-type intrinsic drift layer, both the conventional drift layer and the super-junction drift layer are fully depleted, and thus the super-junction drift layer behaves macroscopically like an intrinsic region. In this effective intrinsic region, an electric field, E, is substantially constant, and therefore breakdown voltage is proportional to electric field times a length, L, of the drift layer (i.e., BV=E·L). Since on-resistance is proportional to the length L of the drift layer, the on-resistance will be proportional to breakdown voltage (i.e., R_{ON}˜BV).

Various semiconductor fabrication techniques have been used in an attempt to develop a charge balance region but either suffer from high cost associated with long manufacturing times or suffer from high defect rates associated with their respective process methods. For example, as previously explained, both the multi-epi implant and trench refill fabrication methods offer little or no improvement in density due, at least in part, to the inherent limitations of the processing equipment and associated methodologies. Hence, there is a need to offer a manufacturing method that can continue to scale to higher density structures (e.g., deep, narrow, high aspect ratio trenches) which offer improved cost and super junction device performance. As will be described in further detail below, embodiments of the invention advantageously address deficiencies present in conventional devices and/or fabrication methodologies.

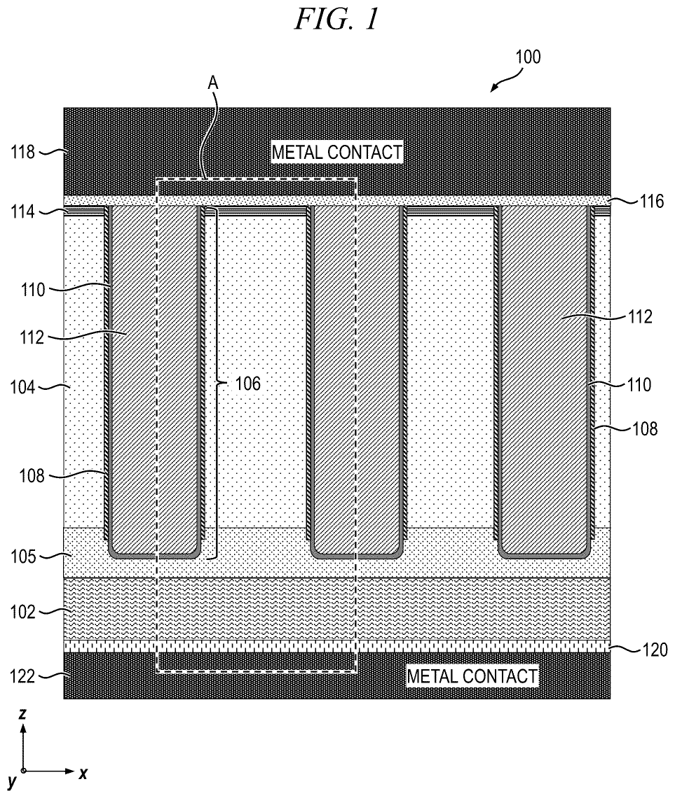

FIG. 1 is a schematic cross-sectional view depicting at least a portion of a semiconductor device 100 including a charge balance region, according to one or more embodiments of the inventive concept. The semiconductor device 100 in this example embodiment is a vertical power device; specifically, a Schottky diode. It is to be appreciated, however, that embodiments are not limited to the particular semiconductor device shown and described herein.

Referring to FIG. 1, the semiconductor device 100 includes a substrate 102 of a first conductivity type, which may be N-type in this embodiment. In one or more embodiments, the substrate 102 may comprise silicon that is doped with an impurity, such as, for example, arsenic, at a prescribed doping concentration level. In some embodiments, the substrate 102 is heavily doped (N+), for example having a doping concentration level greater than about 1×10¹⁹ atoms/cm³, although embodiments are not limited thereto. A bulk epitaxial layer 104, which may be referred to as a drift region, is formed on at least a portion of an upper surface of the substrate 102. In one or more embodiments, the epitaxial layer 104 may be doped with an N-type impurity, such as, for example phosphorous, at a doping concentration level (N) that is less than the doping concentration level of the substrate 102 (e.g., about 1×10¹⁶ atoms/cm³). Although the epitaxial layer 104, in this embodiment, may be formed having N-type conductivity (like the substrate 102), it is to be appreciated that a P-type epitaxial layer may alternatively be employed.

The semiconductor device 100 may include a diffusion layer 105 disposed between the substrate 102 and the epitaxial layer 104. The diffusion layer 105 represents a transition region between the more heavily doped N+ substrate 102 and the more lightly doped N-type epitaxial layer 104, since a change in doping concentration levels between the substrate 102 and epitaxial layer 104 generally does not occur instantaneously; that is, the transition between doping concentration levels of the substrate 102 and the epitaxial layer 104 may not be well-defined. Rather, there will likely be a gradual change in doping concentration levels between the substrate 102 and epitaxial layer 104 due at least in part to diffusion.

The semiconductor device 100 includes one or more recessed features 106, which in this embodiment may be formed as deep trenches. Each of the recessed features 106 extends vertically (i.e., in a z-direction), perpendicular to the upper surface of the substrate 102, from an upper surface of the epitaxial layer 104, through the epitaxial layer 104 and at least partially into the diffusion layer 105, between the epitaxial layer 104 and substrate 102. The recessed features 106, in one or more embodiments, extend longitudinally in a first horizontal direction (i.e., y-direction), parallel to the upper surface of the substrate 102, and are separated from one another in a second horizontal direction (i.e., x-direction), parallel to the upper surface of the substrate 102 and intersecting the first horizontal direction. In one or more embodiments, each of the recessed features 106 may be formed as a high aspect ratio (AR) trench using, for example, a deep reactive ion etching (DRIE) or an alternative process. In some embodiments, each of the recessed features 106 may be configured having an aspect ratio (depth-to-width) of about 10:1 or greater, such as, for example, about 40:1 or greater in some embodiments, with a spacing between adjacent trenches, referred to herein as pitch, that is relatively tight (e.g., about 2 μm), although embodiments are not limited thereto. A tighter pitch beneficially reduces the size of the semiconductor device 100 and/or allows higher density circuitry to be fabricated in the device 100.

An electrically insulating layer 108, for example, an interlayer dielectric (ILD) layer, may be provided on at least sidewalls of the recessed features 106. The insulating layer 108 may comprise a thin-film dielectric material, such as an oxide (e.g., silicon dioxide), an organic polymer, standard tetraethyl orthosilicate (TEOS), or the like, which may be grown or deposited over inner surfaces of the recessed features 106 (e.g., sidewalls and/or bottom) using plasma-enhanced chemical vapor deposition (PECVD), although embodiments are not limited thereto. Although the insulating layer 108 can be deposited (e.g., using PECVD), the insulating layer 108, in one or more embodiments, is grown via thermal processing. A thermally grown layer is generally of higher quality compared to a deposited layer because it repairs sidewall damage sites resulting from the trench etch process. These damage sites can create interface traps that can become charged, which should be avoided in this structure.

A resistive layer 110 is provided on the insulating layer 108 and on sidewalls and/or a bottom of each of the recessed features 106. The insulating layer 108, which is disposed between the resistive layer 110 and the epitaxial layer 104, serves to electrically isolate the resistive layer 110 from the epitaxial layer 104.

In one or more embodiments, the resistive layer 110 may conformally cover the insulating layer 108 and inner surfaces (i.e., sidewalls and/or bottom) of the recessed features 106. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The term “cover” (or “covering,” “covers,” or like terms), as may be used herein, is intended to broadly refer to an element, structure or layer that is on or over another element, structure or layer, either directly or with one or more other intervening elements, structures or layers therebetween.

In one or more embodiments, the resistive layer 110 may comprise a material having a resistivity of about 10⁶ to about 10¹² ohms-centimeter (Ω-cm), although embodiments are not limited thereto. It is to be appreciated that when the resistivity of the resistive layer 110 is less than about 10⁶ Ω-cm, a leakage current in the device may be too high for certain applications, but may still be acceptable for some limited applications. And thus a resistivity range of about 10⁶ to 10¹² Ω-cm for the resistive layer 110 is generally suitable for most applications. In some embodiments, the resistive layer 110 may comprise a combination of aluminum oxide (Al₂O₃) and molybdenum trioxide (MoO₃). The aluminum oxide material is an insulator which, after combining with molybdenum trioxide (also an insulator) and after thermal processing, such as, for example, rapid thermal processing (RTP) (e.g., at about 1000 degrees Celsius), becomes a resistive Al₂O₃—MoO₃ compound.

In one or more non-limiting embodiments, the resistive layer 110 is deposited using atomic layer deposition (ALD). ALD is a thin-film deposition technique based on the sequential use of a gas-phase chemical process (e.g., chemical vapor deposition (CVD)) that can be used to achieve substantially uniform deposition on structures having high aspect ratios, such as the inner surfaces of the recessed features 106. The resistive layer 110 provides an electrical path for current to flow between the diffusion layer 105 and an upper surface of the epitaxial layer 104. As will be explained in further detail below, when the semiconductor device 100 is reverse biased, current flowing through the resistive layer 110 is used to deplete the region of the epitaxial layer 104 (i.e., drift region) between adjacent recessed features 106 to thereby provide charge balancing in the semiconductor device 100.

Optionally, each of the recessed features 106 may be filled with a dielectric material 112. The term “filled” (or “filling,” “fills,” or like terms), as may be used herein, is intended to refer broadly to either completely filling a defined space (e.g., the recessed features 106) or partially filling the defined space; that is, the defined space need not be entirely filled but may, for example, be partially filled or have voids or other spaces throughout. In one or more embodiments, the dielectric material 112 comprises a low-charge dielectric, such as, for example, TEOS and/or borophosphorous tetraethyl orthosilicate (BPTEOS), which may be deposited using a sub-atmospheric chemical vapor deposition (SACVD) process, although embodiments are not limited thereto. Although shown as a homogeneous layer, the dielectric material 112 may comprise a plurality of different materials. The dielectric material 112 is used primarily to provide a planar upper surface of the epitaxial layer 104 for subsequent processing steps in fabricating the semiconductor device 100, but also provides structural support for the semiconductor device 100.

In the case where the semiconductor device 100 is a Schottky diode, as shown in FIG. 1, a Schottky contact 114 may be provided on the upper surface of the epitaxial layer 104 between adjacent recessed features 106. The Schottky contact (i.e., Schottky barrier) 114 may comprise a silicide, such as, for example, platinum silicide, although embodiments are not limited thereto. In one or more embodiments, the Schottky contact 114 may be formed by depositing a thin transition metal (e.g., platinum, titanium, nickel, cobalt, tungsten, etc.) on the upper surface of the epitaxial layer 104. After thermal processing (e.g., annealing), the transition metal will react with exposed silicon in the epitaxial layer 104 to form a low-resistance transition metal silicide. The transition metal does not react with silicon dioxide or other insulating materials present on the wafer. Following the reaction, any remaining transition metal may be removed by chemical etching, leaving silicide contacts in regions of the device between adjacent recessed features 106.

It is to be appreciated that the term “exposed” (or “exposes,” or like terms) may be used herein to describe relationships between elements and/or with reference to intermediate processes in fabricating an integrated circuit device, but may not require exposure of a particular element in the completed device. Likewise, the term “not exposed” may be used to described relationships between elements and/or with reference to intermediate processes in fabricating an integrated circuit device, but may not require a particular element to be unexposed in the completed device.

An upper surface of the Schottky contact 114 may be coplanar with (i.e., at the same vertical level as) an upper surface of the insulating layer 108, the resistive layer 110 and the dielectric material 112 filling the recessed features 106, relative to the upper surface of the substrate 102 as a reference layer. A first adhesion layer (i.e., ohmic layer) 116 extending in the second horizontal direction (i.e., x-direction) may be provided on at least a portion of the upper surfaces of the insulating layer 108, the resistive layer 110, the dielectric material 112 and the Schottky contact 114. In some embodiments, the first adhesion layer 116 may comprise titanium (Ti) and/or titanium nitride (TiN) and serves, at least in part, to facilitate enhanced adhesion between the underlying Schottky contact 114 and a first metal contact 118 provided on an upper surface of the first adhesion layer 116. The first adhesion layer 116, which is electrically conductive, is particularly beneficial in a thick metal deposition process that may be used to form the first metal contact 118.

Similarly, a second adhesion layer 120 may be provided on a back surface of the substrate 102. In some embodiments, the second adhesion layer 120, which is electrically conductive, may comprise, for example, titanium (Ti), nickel (Ni) and/or silver (Ag) and serves, at least in part, to facilitate adhesion between the underlying substrate 102 and a second metal contact 122 provided on a back surface of the second adhesion layer 120. The second adhesion layer 120 is particularly beneficial in a thick metal deposition process that may be used to form the second metal contact 122. The first and second adhesion layers 116, 120 may comprise the same material, although embodiments are not limited thereto. The first and second metal contacts 118 and 122, respectively, may be used as electrode connections of the semiconductor device 100.

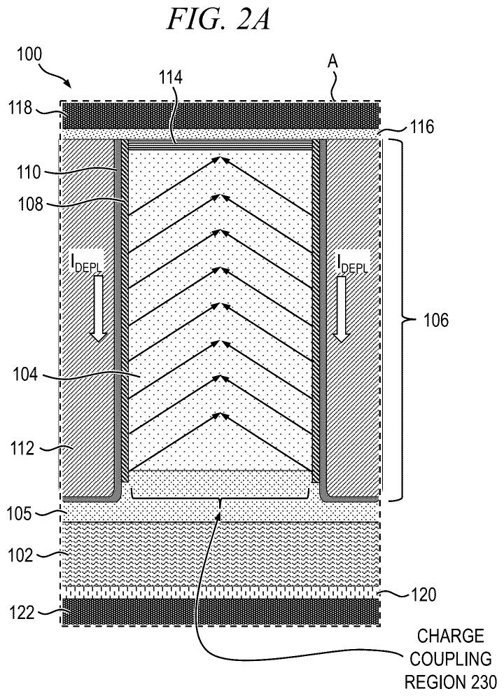

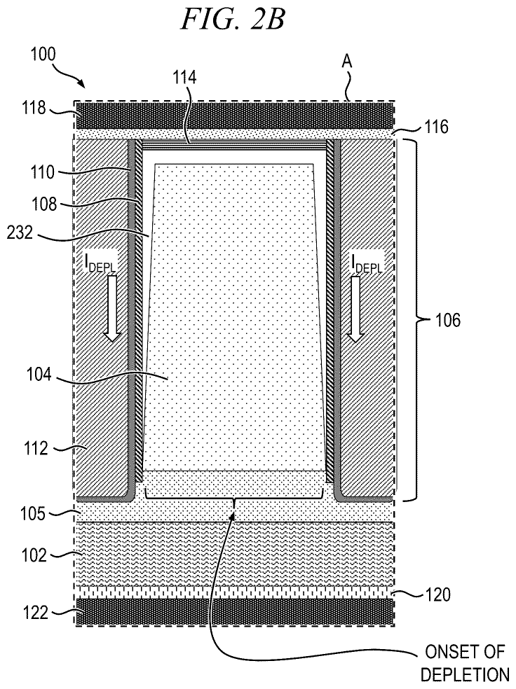

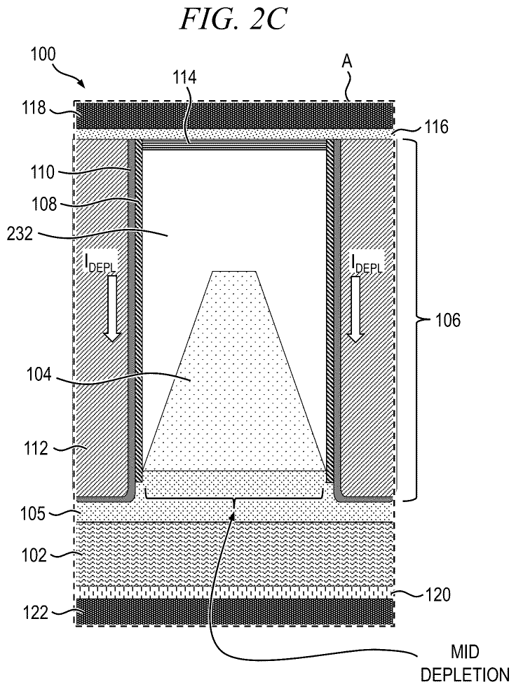

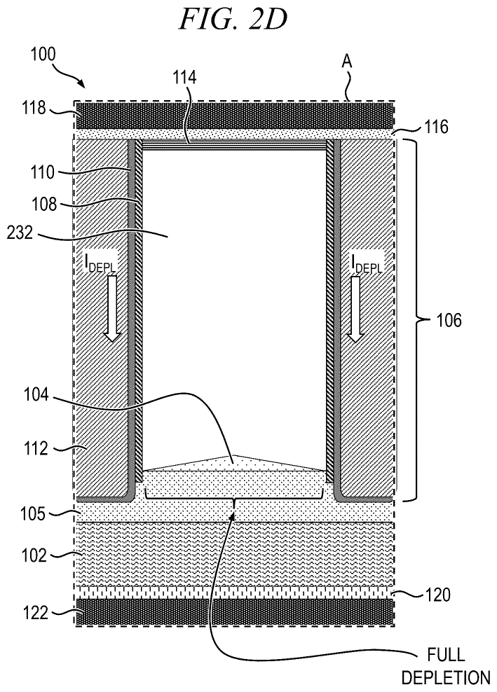

In terms of operation, the semiconductor device 100 is configured such that when the device is reverse-biased, such as by application of a voltage potential between the first and second metal contacts 118 and 122, a current will flow between the first metal contact 118 and the second metal contact 122 via the resistive layer 110, through the diffusion layer 105, the substrate 102, and the first and second adhesion layers 116 and 120, respectively. The resistive layer 110 capacitively couples with the epitaxial layer 104 proximate to the recessed features 106 to deplete the region of the epitaxial layer 104 between adjacent recessed features 106, as will be described in further detail below in conjunction with FIGS. 2A-2D. However, unlike some charge balance approaches which rely heavily on process characteristics and are therefore significantly affected by process variations, the charge balance approach according to embodiments of the inventive concept is dependent primarily on the amount of current flowing through the resistive layer 110, such that the more current that flows through the resistive layer 110, the more the epitaxial layer 104 will deplete. Thus, variations in process characteristics of the epitaxial layer 104, which could otherwise offset the charge compensation of the epitaxial layer 104 in a fixed charge balance approach, can be beneficially compensated for by controlling (i.e., increasing or decreasing) the current flowing through the resistive layer 110. According to aspects of the inventive concept, charge balancing in the semiconductor device 100 is essentially unaffected by variations in the characteristics of the epitaxial layer 104; as long as there is sufficient current flowing through the resistive layer 110, the semiconductor device 100 will charge compensate and eventually fully deplete the drift region/epitaxial layer 104 between adjacent recessed features 106.

FIGS. 2A-2D are schematic cross-sectional views depicting an enlarged region A of the example semiconductor device 100 shown in FIG. 1 conceptually illustrating the formation of a depletion region in the epitaxial/drift layer of the device, according to one or more embodiments. Referring to FIG. 2A, the epitaxial/drift layer 104 between adjacent recessed features 106 in the semiconductor device 100 has an electrical path (provided by the resistive layer 110) along both of its sidewalls. The recessed features 106 may be configured such that they have no static charge associated therewith. When the semiconductor device 100 is reverse biased, such as by applying a prescribed voltage potential between the first and second metal contacts 118 and 122, a current, I_{DEPL}, will flow through the resistive layer 110 in each of the recessed features 106. Thus, the resistive layer 110 provides a current path between the first metal contact 118 (via the first adhesion layer 116) and the second metal contact 122 (through the second adhesion layer 120, the substrate 102, and the diffusion layer 105).

The applied voltage is distributed uniformly in a vertical direction in the resistive layer 110 and is supported in the horizontal direction analogous to a capacitor, in which one plate is the resistive layer 110 and the other plate is the non-depleted epitaxial layer (i.e., drift region) 104. The capacitive coupling will charge compensate the drift region 104 to form a charge coupling region 230 and initiates the onset of depletion. More particularly, the current I_{DEPL} flowing in the resistive layer 110 of one recessed feature 106 will operate in parallel (i.e., in conjunction) with the current I_{DEPL} flowing in the resistive layer 110 of an adjacent recessed feature 106 in forming the charge coupling region 230; in other words, the resistive layer 110 on either side of the epitaxial/drift region 104 between adjacent recessed features 106 will work together in parallel to deplete the epitaxial layer 104 since both resistive layers 110 will be at the same potential. FIG. 2B conceptually depicts the onset of a depletion region 232 being formed in the epitaxial layer 104 between adjacent recessed features 106.

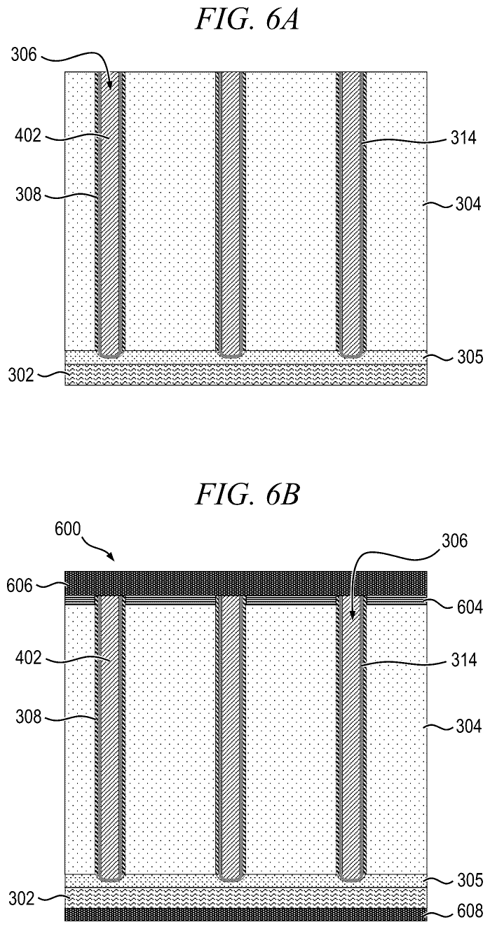

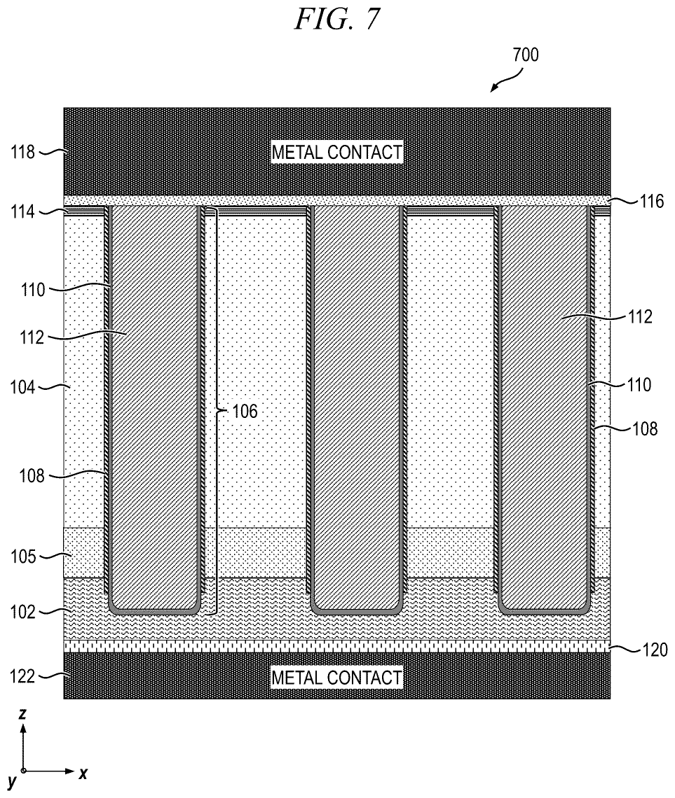

The dielectric of this so-called coupling capacitor is the electrically insulating layer 108 (e.g., silicon dioxide) plus the depleted portion of the epitaxial layer 104 (i.e., depletion region 232). The electrically insulating layer 108 assures uniform vertical voltage distribution by preventing the current I_{DEPL} from flowing horizontally and locally into the epitaxial layer 104 at any point other than at a bottom contact of the resistive layer 110 to the diffusion layer 105 (or, in some embodiments (see FIG. 6), to the substrate 102 or, in another embodiment (see FIG. 7), at the bottom of epitaxial layer 104). The electrically insulating layer 108 may be configured to withstand the horizontal depletion voltage.

As the applied voltage is increased, the current I_{DEPL} in the resistive layer 110 also continues to increase, which in turn increases the amount of charge compensation that occurs within the non-depleted epitaxial layer 104. This results in a transition from onset depletion (FIG. 2B) to mid depletion as shown in FIG. 2C, wherein the area of the depletion region 232 is about equal to the area of the non-depleted epitaxial layer 104 between adjacent recessed features 106. Eventually, as the current I_{DEPL} in the resistive layer 110 increases further and eventually reaches a prescribed amount, the epitaxial/drift layer 104 will be fully depleted of free charge carriers to form the full depletion region 232 shown in FIG. 2D. This depletion region 232 will form in the epitaxial layer 104 independently of the characteristics of the epitaxial layer 104; that is, the depletion region 232 is insensitive to dopant variations in the epitaxial layer 104 because the resistive layer 110 is locally charged to whatever voltage is needed to match the total epitaxial dopant.

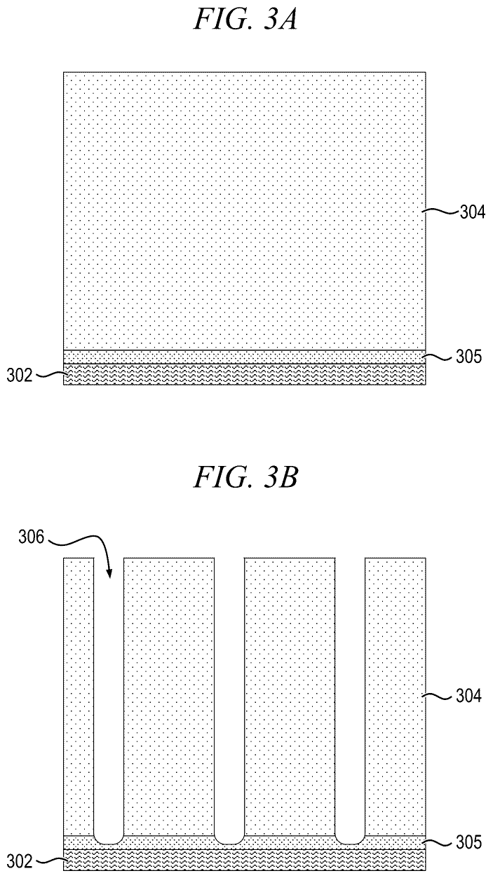

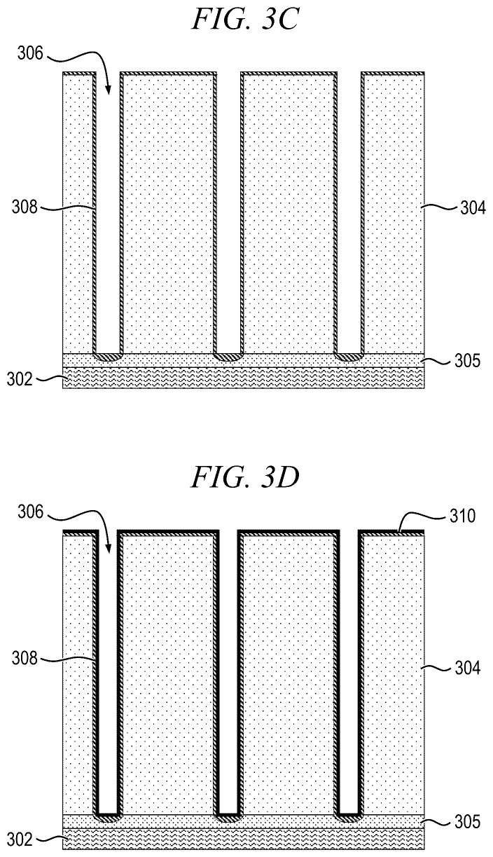

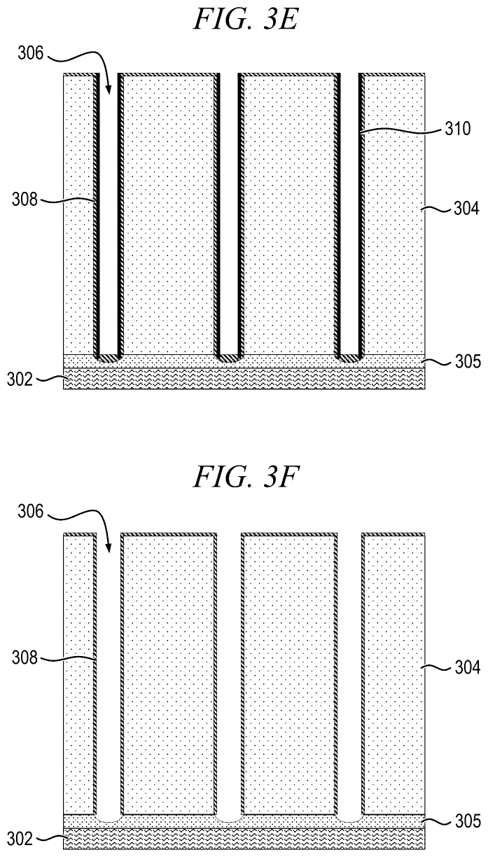

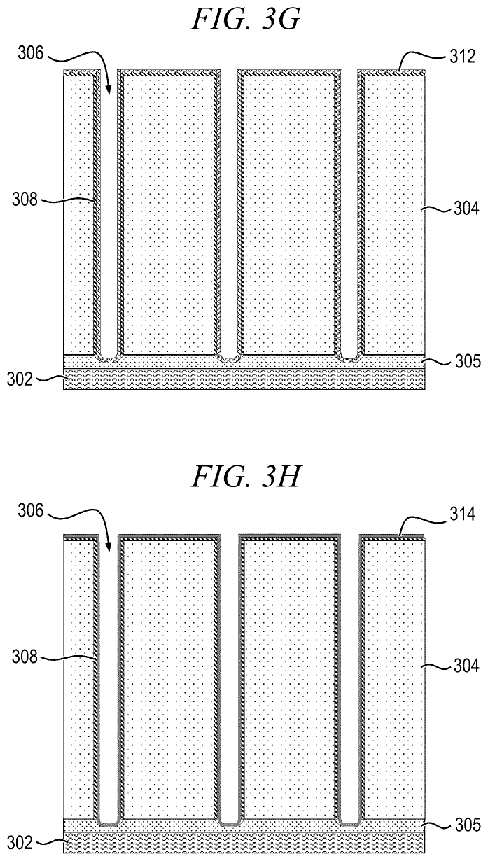

FIGS. 3A-3H are schematic cross-sectional views depicting intermediate processes in an illustrative method for fabricating a charge balanced semiconductor device, such as the example semiconductor device 100 shown in FIG. 1, according to one or more embodiments of the inventive concept. Referring to FIG. 3A, the semiconductor device includes a substrate 302 of a first conductivity type. In one or more embodiments, the substrate 302 comprises a semiconductor material, such as silicon, silicon carbide, gallium arsenide, etc., that is doped with an impurity (e.g., arsenic, phosphorous, boron, etc.) at a prescribed doping concentration level. In some embodiments, the substrate 302 is heavily doped with arsenic to have N-type conductivity (N+), for example having a doping concentration level greater than about 1×10¹⁹ atoms/cm³, although embodiments are not limited thereto.

A bulk epitaxial layer 304, which may be referred to as a drift layer, is formed on at least a portion of an upper surface of the substrate 302. In one or more embodiments, the epitaxial layer 304 may be doped with an N-type impurity, such as, for example phosphorous, at a doping concentration level that is less than the doping concentration level of the substrate 302 (e.g., about 1×10¹⁶ atoms/cm³). Although the epitaxial layer 304 in this embodiment may be formed having the same conductivity type (e.g., N-type) as the substrate 302, it is to be appreciated that embodiments are not limited thereto. For example, a P-type epitaxial layer 304 may alternatively be employed, such as by doping the epitaxial layer with boron, or an alternative P-type dopant.

The semiconductor device may include a diffusion layer 305 disposed between the substrate 302 and the epitaxial layer 304. As previously explained in conjunction with FIG. 1, the diffusion layer 305 represents a transition region between the more heavily doped N+ substrate 302 and the more lightly doped N-type epitaxial layer 304, since a change in doping concentration levels between the substrate 302 and epitaxial layer 304 does not occur instantaneously, but instead there will be a gradual change in doping concentration levels between the substrate 302 and epitaxial layer 304 due at least in part to diffusion.

Referring to FIG. 3B, one or more recessed features 306 may be provided in the semiconductor device. In some embodiments, the recessed features 306 may be formed as deep, high aspect ratio trenches, such as by using DRIE or an alternative trench formation process. Each of the recessed features 306 is configured to extend vertically (i.e., in a direction perpendicular to the upper surface of the substrate 302) through the epitaxial layer 304 and at least partially into the diffusion layer 305. In this manner, the diffusion layer 305 is exposed through a bottom of the recessed features 306.

In one or more embodiments, for an illustrative device with a 600-volt breakdown voltage rating, each of the recessed features 306 may be formed having a depth, from an upper surface of the epitaxial layer 304, of about 40 microns (μm) or more and having a width of about 1 μm or less, although embodiments are not limited to any specific dimensions of the recessed features 306 as long as the recessed features 306 extend at least partially into the underlying diffusion layer 305. A spacing between adjacent recessed features 306 (i.e., pitch) may be about 1 μm, although embodiments of the invention are not limited to any particular spacing. Furthermore, it is to be appreciated that although three recessed features 306 are shown in FIGS. 3A-3H, embodiments of the inventive concept are not limited to any particular number of recessed features 306 formed in the semiconductor device.

With reference to FIG. 3C, an insulating layer 308 may be formed on at least sidewalls of each of the recessed features 306 and on an upper surface of the epitaxial layer 304. In one or more embodiments, the insulating layer 308 may be formed on sidewalls and a bottom of each of the recessed features 306. In the insulating layer 308 on the bottom of the recessed features 306 may be thicker than the insulating layer 308 on the sidewalls of the recessed features 306. In some embodiments, the insulating layer 308 may fill the bottom of the recessed features 306 such that an upper surface of the insulating layer 308 in the bottom of the recessed features is coplanar with the upper surface of the diffusion layer 305, although embodiments are not limited thereto. In embodiments where no insulating layer 308 is formed on the bottom of the recessed features 306, the insulating layer 308 is formed on the sidewalls of the recessed features 306 such that the epitaxial layer 304 defining the sidewalls of the recessed features 306 is not exposed in the recessed features 306; that is, the insulating layer 308 is configured to cover the epitaxial layer 304 in the recessed features 306. The insulating layer 308 may be formed as an ILD layer using a thermal growth process (which is preferred for repairing sidewall damage of the recessed features 306, as previously explained), or deposited using tools such as SACVD or PECVD, although embodiments are not limited thereto.

In FIG. 3D, a protective layer 310 may be provided on the insulating layer 308. In one or more embodiments, the protective layer 310 is formed on exposed inner surfaces of the insulating layer 308 on sidewalls and the bottom of the recessed features 306 and on an upper surface of the insulating layer 308 extending laterally on the upper surface of the epitaxial layer 304. The protective layer 310 may comprise, for example, a nitride (e.g., silicon nitride) formed using an oxide growth or deposition process.

Referring to FIG. 3E, the protective layer 310 on the horizontal surfaces of the device, including the portions of the protective layer 310 at the bottom of the recessed features 306 and over the upper surface of the epitaxial layer 304, is removed, such as by using an anisotropic etching process (e.g., dry plasma etching, RIE, etc.), leaving the protective layer 310 present on the vertical sidewalls of the recessed features 306. In this manner, the insulating layer 308 is exposed through the bottom of the recessed features 306 and on the upper surface of the epitaxial layer 304.

With the protective layer 310 remaining in place on the sidewalls of the recessed features 306, the insulating layer 308 at the bottom of the recessed features 306 can be removed to expose the underlying diffusion layer 305, as shown in FIG. 3F. The portion of the insulating layer 308 at the bottom of the recessed features 306 may be removed, for example, using an isotropic or anisotropic etching process (e.g., wet etching, RIE, dry plasma etching, etc.), selective to the material forming the insulating layer 308. The protective layer 310 on the sidewalls of the recessed features 306 may then be removed, such as by using an isotropic etching process selective to the material used to form the protective layer 310.

Although not explicitly shown in the figures, there may be one or more photolithographic mask steps that occur between the removal of the protective layer 310 and the removal of the insulator layer 308 at the bottom of the recessed features 306. Such photolithographic steps have been omitted herein for clarity and economy of description. However, as will be known by those skilled in the art, photo resist may be provided on the upper surface of the device to protect the insulating layer 308 on the upper surface of the device and allow removal of the insulating layer 308 only at the bottom of the recessed features 306.

With reference to FIG. 3G, a film 312 is deposited on at least sidewalls and, optionally, on a bottom of the recessed features 306, as well as over at least a portion of the upper surface of the epitaxial layer 304. In one or more embodiments, the film 312 comprises a material (or combination of materials) having electrically insulating characteristics, such as a metal oxide, which, after thermal processing, becomes resistive. In some embodiments, the film 312 comprises a composite material including aluminum oxide (Al₂O₃) and molybdenum trioxide (MoO₃), although embodiments are not limited thereto. An Al₂O₃—MoO₃ film 312 may be formed, in some embodiments, by independently depositing Al₂O₃ material and MoO₃ material using ALD, and then after performing thermal processing a composite resistive layer is formed. In other embodiments, a resistive material may be atomic layer deposited on at least sidewalls of the recessed features 306, thereby eliminating the need for thermal processing. In some embodiments, even when the film 312 comprises a resistive material that is deposited on at least the sidewalls of the recessed features 306, thermal processing may still be performed to fine tune (i.e., modify) the resistive properties of the film 312 as desired. In one or more embodiments, the film 312 may comprise a single-layer material, such as, for example, titanium oxide (TiO₂), hafnium oxide (HfO₂), tungsten trioxide (WO₃), or the like, or the film 312 may comprise a multilayer composite material, such as, for example, titanium hafnium nitride (TiHfN), titanium molybdenum nitride (TiMoN), or the like, although embodiments are not limited thereto.

The film 312 is preferably deposited using ALD, which provides a well-controlled conformal coating along inner surfaces of high-aspect-ratio structures such as the recessed features 306. In some embodiments, a cross-sectional thickness of the film 312 on the sidewalls and bottom of the recessed features 306 can range from about 10 Angstroms (Å) to 100 Å, although the inventive concept is not limited thereto.

Using sequential, self-limiting surface reactions, ALD is able to achieve precise thickness control at an Angstrom or monolayer level. Most ALD processes are based on binary reaction sequences where two surface reactions occur and deposit a binary compound film. Because there are only a finite number of surface sites, the reactions can only deposit a finite number of surface species. Assuming each of the two surface reactions is self-limiting, the two reactions may proceed in a sequential fashion to deposit a thin film with atomic level control. The self-limiting nature of ALD leads to excellent step coverage and is fully conformal on high-aspect-ratio structures, such as on the bottom and sidewalls of the recessed features 306. Moreover, the ALD process can be integrated with a standard semiconductor fabrication process without impacting other semiconductor fabrication steps that are temperature sensitive.

More particularly, according to one or more embodiments, once the recessed features 306 are formed through the epitaxial layer 304 and the sidewalls of the recessed features 306 are protected from the exposed epitaxial layer 304 using the insulating layer 308, an ALD process is used to conformally deposit the film 312 on the bottom and sidewalls of the recessed features 306. When used with ALD, a metal oxide (or other material) can be deposited on the bottom and sidewalls of the recessed features 306, even when the recessed features 306 are formed as high-aspect-ratio trenches.

The semiconductor device may then be subjected to thermal processing whereby at least a portion of the electrically insulating film 312 (FIG. 3G) proximate the recessed features 306 becomes a resistive film 314, as shown in FIG. 3H. For example, thermal processing at a temperature range of about 500 to 1000 degrees Celsius for a duration range of about 30 to 120 seconds may be performed, although embodiments are not limited thereto. It is to be appreciated that the thermal processing temperature and duration may be controlled to obtain a desired resistivity of the resistive film 314 and may be a function of the type of material used for the film 312 (FIG. 3G). It is to be appreciated that for embodiments in which thermal processing is not required, such as, for example, when the deposited film 312 comprises a resistive material that does not require “tuning” of the resistive properties, the resistive film 314 may be the same as the deposited film 312 shown in FIG. 3G.

The resistive film 314 may comprise a material having a resistivity of about 10⁶ to about 10¹² ohms-centimeter (Ω-cm), although embodiments are not limited thereto. For example, in some embodiments, the resistive film 314 may comprise a combination of aluminum oxide (Al₂O₃) and molybdenum trioxide (MoO₃). The aluminum oxide material is an insulator which, after combining with molybdenum trioxide (also an insulator) and after performing thermal processing (e.g., at a range of about 500 to 1000 degrees Celsius), becomes a resistive Al₂O₃—MoO₃ compound. In this manner, a current path is provided between the upper surface of the epitaxial layer 304 and the diffusion layer 305. The insulating layer 308 on at least a portion of the sidewalls of the recessed features 306, between the resistive film 314 and the epitaxial layer 304, serves to electrically isolate the resistive film 314 from the epitaxial layer 304.

Following thermal processing to form the resistive film 314, the recessed features 306 may be at least partially filled with a fill material (e.g., dielectric material 112 shown in the illustrative semiconductor device 100 of FIG. 1) to provide a planar upper surface of the semiconductor device for the subsequent fabrication of active devices.

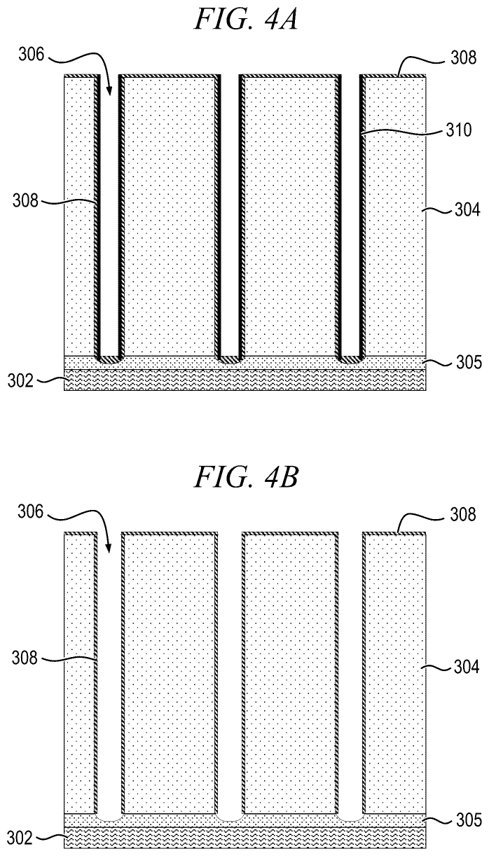

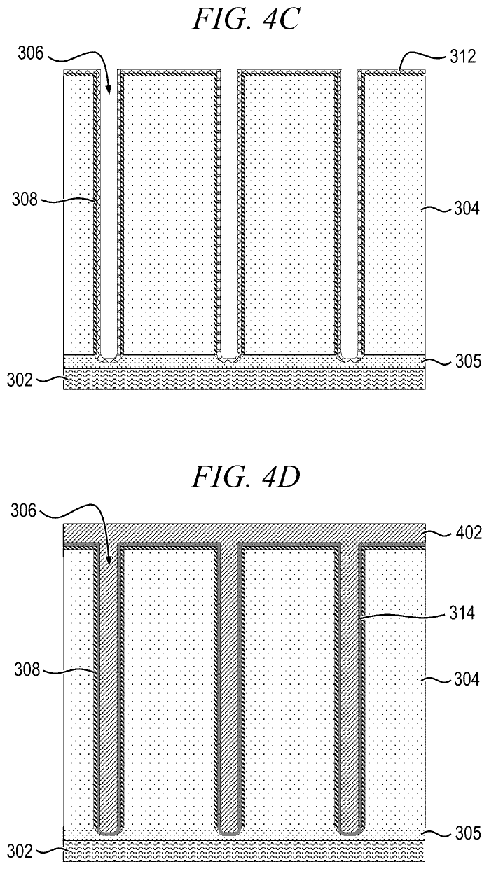

The illustrative method described in conjunction with FIGS. 3A-3H is one approach for fabricating the example semiconductor device 100 shown in FIG. 1 according to one or more embodiments of the inventive concept, however other fabrication processes may be similarly employed and are within the scope of the present disclosure. By way of example only and without limitation, FIGS. 4A-4D are schematic cross-sectional views depicting alternative intermediate processes in an illustrative method for fabricating a charge balanced semiconductor device, according to one or more embodiments of the inventive concept. Referring to FIG. 4A, which continues based on the device structure shown in FIG. 3D and may be consistent with the intermediate process(es) shown in FIG. 3E, the protective layer 310 on the horizontal surfaces of the device, including the portions of the protective layer 310 at the bottom of the recessed features 306 and over the upper surface of the epitaxial layer 304, may be removed, such as by using an anisotropic etching process (e.g., dry plasma etching, RIE, etc.), leaving the protective layer 310 present on the vertical sidewalls of the recessed features 306. After removal of the portions of the protective layer 310 disposed on horizontal surfaces of the device structure, the insulating layer 308 is exposed through the bottom of the recessed features 306 and on the upper surface of the epitaxial layer 304.

With reference to FIG. 4B, the portion of the insulating layer 308 exposed through the bottom of the recessed features 306 can be removed, with the protective layer 310 remaining on the sidewalls of the recessed features 306, to thereby expose the underlying diffusion layer 305 through the bottom of the recessed features 306. As previously stated in conjunction with FIG. 3F, the portion of the insulating layer 308 at the bottom of the recessed features 306 may be removed using an isotropic or anisotropic etching process (e.g., wet etching, RIE, dry plasma etching, etc.), selective to the material forming the insulating layer 308. The protective layer 310 on the sidewalls of the recessed features 306 may then be removed, such as by using an isotropic etching process selective to the material used to form the protective layer 310, leaving the insulating layer 308 on the sidewalls of the recessed features 306 and on the upper surface of the epitaxial layer 304.

Referring to FIG. 4C, a film 312 is deposited on at least sidewalls and, optionally, on a bottom of the recessed features 306, as well as over at least a portion of the upper surface of the epitaxial layer 304. The film 312 is deposited using ALD, which provides a well-controlled conformal coating along inner surfaces of high-aspect-ratio structures such as the recessed features 306. In some embodiments, a cross-sectional thickness of the film 312 on the sidewalls and bottom of the recessed features 306 can range from about 10 Å to 100 Å, although the inventive concept is not limited thereto. The deposited film 312 may comprise a material (or combination of materials) that exhibits electrically insulating characteristics, such as a metal oxide. In one or more embodiments, the film 312 comprises a composite material including aluminum oxide (Al₂O₃) and molybdenum trioxide (MoO₃), although embodiments are not limited thereto. A percentage of aluminum oxide in the film 312 comprising Al₂O₃—MoO₃ material may be varied to control one or more properties of the film 312, as will become apparent to those skilled in the art.

Before performing thermal processing to convert the film 312 to a resistive film or otherwise fine tune the resistive properties of the film 312, as was described in conjunction with FIGS. 3G and 3H, the recessed features 306 are at least partially filled with a fill material 402, as shown in FIG. 4D. Referring to FIG. 4D, in one or more embodiments, the recessed features 306 may be filled using a blanket deposition process whereby an oxide (e.g., silicon dioxide or the like) is deposited on the wafer, including on at least a portion of the upper surface of the epitaxial layer 304 and at least partially filling the recessed features 306.

In one or more embodiments, the fill material 402 may comprise a low-charge dielectric, such as, for example, TEOS and/or BPTEOS, which may be deposited using an SACVD process, although embodiments are not limited thereto. Although shown as a homogeneous layer, the fill material 402 may comprise a plurality of different materials, or it may contain voids throughout. The fill material 402 is used primarily to provide a planar upper surface of the epitaxial layer 304 for subsequent processing steps in fabricating one or more active devices in the semiconductor device.

The deposition of the fill material 402 is followed by thermal processing, whereby at least a portion of the electrically insulating film 312 (FIG. 4C) proximate the recessed features 306 is converted to a resistive film 314. For example, thermal processing at a temperature range of about 500 to 1000 degrees Celsius for a duration range of about 30 to 120 seconds may be performed, although embodiments are not limited thereto.

It is to be understood that the thermal processing temperature and/or duration may be controlled so as to obtain a target resistivity of the resistive film 314, depending on the type of material used for the film 312 (FIG. 4C). In one or more embodiments, the target resistivity of the resistive film 314 may be about 10⁶ to about 10¹² Ω-cm, although embodiments are not limited thereto. For example, the resistive film 314 may comprise a combination of aluminum oxide (Al₂O₃) and molybdenum trioxide (MoO₃). The aluminum oxide material is an insulator which, after combining with molybdenum trioxide (also an insulator) and after performing thermal processing, becomes a resistive Al₂O₃—MoO₃ compound. In this manner, a current path is provided between the upper surface of the epitaxial layer 304 and the diffusion layer 305. The insulating layer 308 on at least a portion of the sidewalls of the recessed features 306, between the resistive film 314 and the epitaxial layer 304, serves to electrically isolate the resistive film 314 from the epitaxial layer 304.

It has been established that using an Al₂O₃ layer proximate to a silicon layer may generate negative fixed charge, which may not be beneficial when used in conjunction with aspects of the inventive concept. (See, e.g., R. Kotipalli, et al., “Passivation Effects of Atomic-Layer-Deposited Aluminum Oxide,” EPJ Photovoltaics 4, 45107 (2013), pp. 1-8, the disclosure of which is incorporated by reference herein in its entirety). In one or more embodiments, a charge prevention layer may be formed on at least sidewalls of the recessed features that will reduce the fixed charge in the Al₂O₃ layer to zero and thereby serves as an interface to prevent trapping of charge carriers in subsequent processing steps. The addition of the charge prevention layer may be incorporated into the fabrication process previously described in connection with FIGS. 3A-4D.

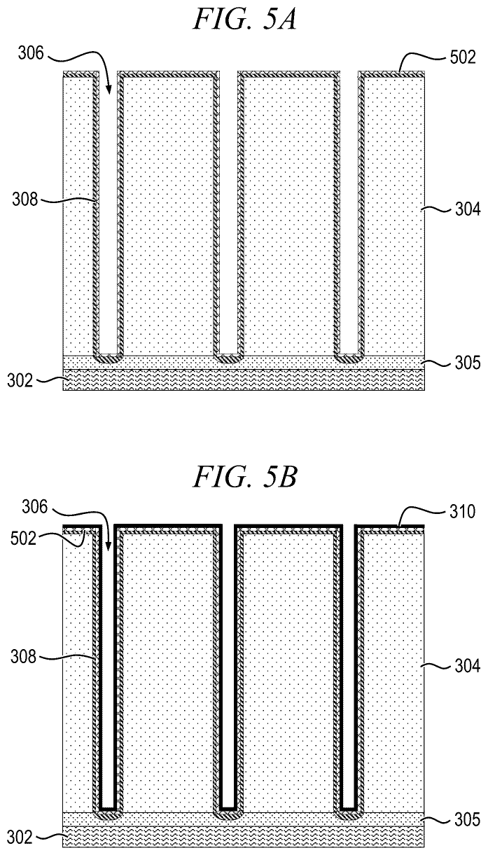

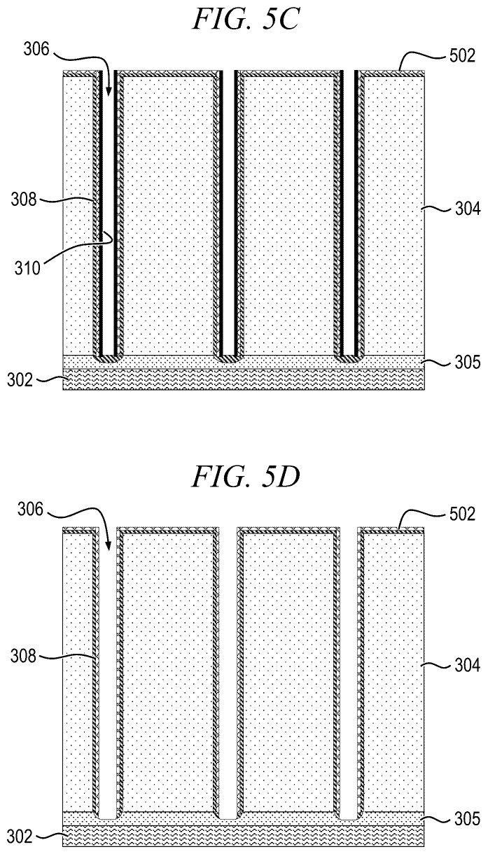

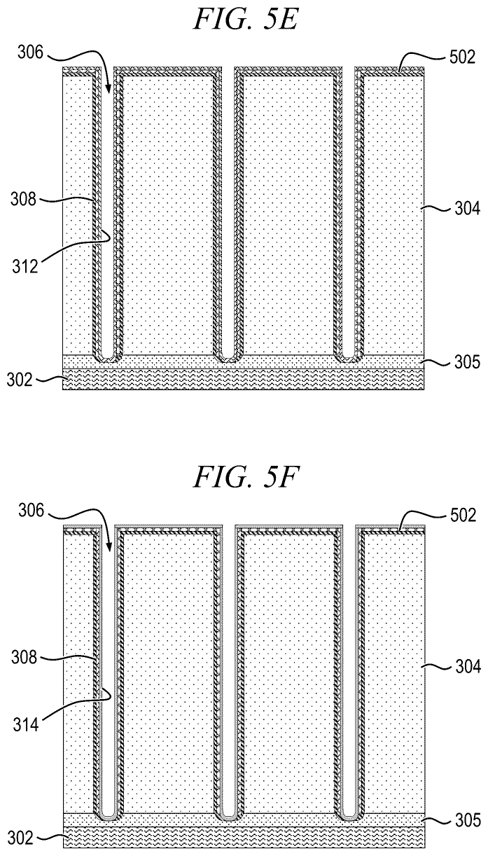

FIGS. 5A-5F are schematic cross-sectional views depicting intermediate processes that may be optionally performed in an illustrative method for fabricating a charge balanced semiconductor device, according to one or more embodiments of the inventive concept. Referring to FIG. 5A, which may be a continuation of the illustrative fabrication process shown in FIG. 3C, a charge prevention layer 502 is provided on the insulating layer 308 formed on the upper surface of the epitaxial layer 304 and on at least sidewalls of the recessed features 306, and preferably on the bottom of the recessed features 306. The charge prevention layer 502 may be formed using ALD, although embodiments are not limited thereto. The charge prevention layer 502 may comprise, for example, hafnium oxide (HfO₂), which has been shown to reduce negative fixed charges in Al₂O₃ to zero (see, e.g., D. K. Simon, et al., “On the Control of the Fixed Charge Densities in Al₂O₃-Based Silicon Surface Passivation Schemes,” ACS Appl. Mater. Interfaces 2015, 7, pp. 28215-28222, the disclosure of which is incorporated by reference herein in its entirety), although embodiments are not limited thereto.

In FIG. 5B, a protective layer 310 may be provided on the charge prevention layer 502. In one or more embodiments, the protective layer 310 is formed on exposed inner surfaces of the charge prevention layer 502 on sidewalls and the bottom of the recessed features 306 and on an upper surface of the charge prevention layer 502 extending laterally on the upper surface of the epitaxial layer 304. The protective layer 310 may comprise, for example, a nitride compound (e.g., silicon nitride) formed using an oxide growth or deposition process.

In FIG. 5C, the protective layer 310 on the horizontal surfaces of the device, including the portions of the protective layer 310 at the bottom of the recessed features 306 and on the upper surface of the charge prevention layer 502 extending on the epitaxial layer 304, may be removed, such as by using an anisotropic etching process (e.g., dry plasma etching, RIE, etc.), leaving the protective layer 310 remaining on the vertical sidewalls of the recessed features 306. The charge prevention layer 502 at the bottom of the recessed features 306 is also removed, leaving the insulating layer 308 exposed through the bottom of the recessed features 306.

With the protective layer 310 remaining on the sidewalls of the recessed features 306, the insulating layer 308 at the bottom of the recessed features 306 is removed to expose the underlying diffusion layer 305, as shown in FIG. 5D. The portion of the insulating layer 308 at the bottom of the recessed features 306 may be removed, for example, using an isotropic or anisotropic etching process (e.g., wet etching, RIE, dry plasma etching, etc.), selective to the material forming the insulating layer 308, as previously described. The protective layer 310 on the sidewalls of the recessed features 306 may then be removed, such as by using an isotropic etching process selective to the material used to form the protective layer 310, leaving the charge prevention layer 502 exposed on the sidewalls of the recessed features 306.

The process continues in a manner consistent with the process described above in connection with FIGS. 3G and 3H. Specifically, a film 312 is deposited on the charge prevention layer 502 on at least the sidewalls of the recessed features 306 as well as on the upper surface of the charge prevention layer 502 extending horizontally over at least a portion of the upper surface of the epitaxial layer 304 and, optionally, on the diffusion layer 305 at the bottom of the recessed features 306, as shown in FIG. 5E. In one or more embodiments, the film 312 comprises a material (or combination of materials) having electrically insulating properties, such as a metal oxide, which, after thermal processing, becomes resistive. In some embodiments, the film 312 comprises a composite material including Al₂O₃ and MoO₃, although embodiments are not limited thereto.

The semiconductor device may then be subjected to thermal processing whereby at least a portion of the electrically insulating film 312 (FIG. 5E) in the recessed features 306 becomes a resistive film 314, as shown in FIG. 5F. As previously explained, the thermal processing temperature and duration may be controlled to obtain a desired resistivity of the resistive film 314 and may be a function of the type of material used for the film 312. For embodiments in which thermal processing is not required, such as, for example, when the deposited film 312 comprises a resistive material that does not require “tuning” of the resistive properties, the resistive film 314 depicted in FIG. 5F may be the same as the deposited film 312 shown in FIG. 5E.

It is to be appreciated that the resistive film 314 may be formed in various ways according to aspects of the inventive concept, some of which have been shown and described herein. For example, in some embodiments the resistive film 314 may comprise a resistive material (e.g., titanium nitride) that is deposited directly on the insulating layer 308 without requiring subsequent thermal processing, as previously stated (see FIG. 3G). In one or more embodiments, the resistive film 314 may comprise an electrically insulating film (e.g., Al₂O₃—MoO₃) which, after subsequent thermal processing, is converted to a resistive film (see FIG. 3H). In other embodiments, the resistive film 314 may be formed as a multilayer structure comprising an electrically insulating film (e.g., Al₂O₃—MoO₃) stacked on a charge prevention layer 502 (e.g., HfO₂, or the like) which is later subjected to thermal processing to convert the electrically insulating film to a resistive film (see FIG. 5E). In other embodiments, the resistive film 314 may comprise a multilayer structure including a charge prevention layer 502 and a resistive film 312, which does not require subsequent thermal processing (see FIG. 5D).

In one or more embodiments, before performing thermal processing to convert the film 312 to a resistive film 314 or fine tuning the resistive properties of the film 312, as was described in conjunction with FIGS. 5E and 5F, the recessed features 306 may be at least partially filled with a fill material (e.g., TEOS and/or BPTEOS), similar to the intermediate process shown in FIG. 4D. For example, the recessed features 306 may be filled using a blanket deposition process whereby an oxide (e.g., silicon dioxide or the like) is deposited on the wafer, including on at least a portion of the upper surface of the epitaxial layer 304 and at least partially filling the recessed features 306, followed by a planarization process (e.g., CMP). The fill material may be used to provide a planar upper surface of the epitaxial layer 304 for subsequent processing steps in fabricating one or more active devices in the semiconductor device. After filling the recessed features 306, thermal processing may be performed to convert the film 312 to a resistive film 314 or to tune the resistive properties of the film 312, as previously described.

FIGS. 6A and 6B are schematic cross-sectional views depicting intermediate processes that may be optionally performed in an illustrative method for fabricating a charge balanced semiconductor device, according to one or more embodiments of the inventive concept. Referring to FIG. 6A, which may be a continuation of the illustrative fabrication process shown in FIG. 4D, an upper surface of the fill material 402 may be planarized, such as by performing chemical-mechanical polishing (CMP) or an alternative planarization process. During planarization, a cross-sectional thickness of the fill material 402 may be reduced (i.e., thinned) until an upper surface of the epitaxial layer 304 is exposed; that is, the epitaxial layer 304 may be used as a planarization stop layer. At the point where the upper surface of the epitaxial layer 304 is exposed, upper surfaces of the insulating layer 308, the resistive film 314 and the fill material 402 will be coplanar with the upper surface of the epitaxial layer 304 (i.e., having the same vertical height), relative to the upper surface of the substrate 302 as a reference layer.

Once the upper surface of the semiconductor structure is planar, additional processing (not explicitly shown but implied) may be performed in fabricating a complete semiconductor device. Such additional processing steps may include, for example, the formation of one or more anode and cathode regions, source and drain regions, collector and emitter regions, etc., depending on the type of active device being formed, including, for example, a diode, field-effect transistor, and/or bipolar transistor, respectively, as will be known by those skilled in the art.

By way of example only and without limitation, FIG. 6B illustrates subsequent processing which may be performed in fabricating a Schottky diode 600, according to one or more embodiments of the inventive concept. Referring to FIG. 6B, a Schottky contact (i.e., Schottky barrier) 604 may be formed in the upper surface of the epitaxial layer 304 extending horizontally (i.e., parallel to the upper surface of the substrate 302) between adjacent recessed features 306. The Schottky contact 604, which may be formed in a manner consistent with the formation of the Schottky contact 114 in the semiconductor device 100 shown in FIG. 1, may comprise a silicide, such as, for example, platinum silicide, although embodiments are not limited thereto.

A first metal contact 606, which may serve as an anode electrode of the Schottky diode 600, may be provided on the upper surface of the structure, including on upper surfaces of the Schottky contact 604 as well as an upper surface of the insulating layer 308, the resistive film 314 and the fill material 402 in the recessed features 306. A second metal contact 608, which may serve as a cathode electrode of the Schottky diode 600, may be provided on a back surface of the substrate 302, opposite the epitaxial layer 304. Although not explicitly shown, adhesion layers (e.g., first and second adhesion layers 116 and 120, respectively, shown in FIG. 1) may be provided between the first metal contact 606 and upper surfaces of the Schottky contact 604, the insulating layer 308, the resistive film 314 and the fill material 402, and between the second metal contact 608 and the back surface of the substrate 302, in a manner consistent to the semiconductor device 100 shown in FIG. 1.

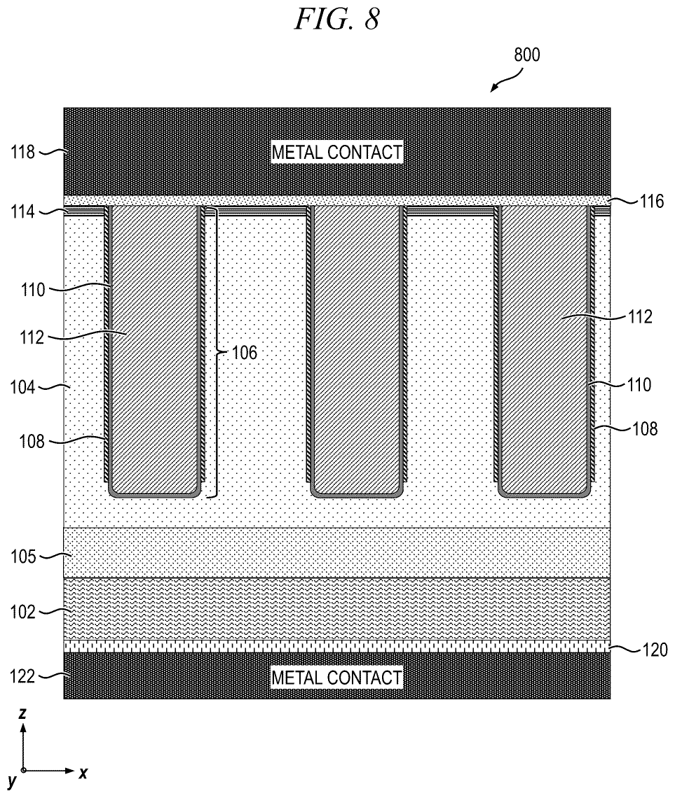

Although in the illustrative semiconductor device 100 shown in FIG. 1, the recessed features 106 were configured to extend vertically through the epitaxial layer 104 and partially into the diffusion layer 105, embodiments of the inventive concept are not limited thereto. By way of example only and without limitation, FIGS. 7 and 8 are schematic cross-sectional views depicting at least a portion of example semiconductor devices including recessed features formed at different depths, according to alternative embodiments of the inventive concept.

Referring to FIG. 7, a semiconductor device 700 includes a plurality of recessed features 106 configured to extend vertically (i.e., in the z-direction) through the epitaxial layer 104, through the diffusion layer 105, and partially into the substrate 102. Like the recessed features 106 shown in FIG. 1, the recess features 106 of the semiconductor device 700 of FIG. 7 may extend longitudinally in the first horizontal direction (i.e., the y-direction) and may be separated from one another in the second horizontal direction (i.e., the x-direction). In the semiconductor device 700, the resistive layer 110 provides a current path between the upper surface of the epitaxial layer 104 and the substrate 102, so that the epitaxial layer 104 may be fully depleted by a current conveyed by the resistive layer 110.

FIG. 8 depicts a semiconductor device 800 that includes a plurality of recessed features 106 configured to extend vertically (i.e., in the z-direction) partially into the epitaxial layer 104, but not into the diffusion layer 105 or the substrate 102. In the semiconductor device 800, the resistive layer 110 will provide a current path between the upper surface of the epitaxial layer 104 and a lower portion of the epitaxial layer 104 (i.e., proximate the bottom of the recessed features 106), so that a prescribed portion of the epitaxial layer 104 may not be fully depleted by a current conveyed by the resistive layer 110. Like the recessed features 106 shown in FIGS. 1 and 7, the recess features 106 of the semiconductor device 800 of FIG. 8 may extend longitudinally in the first horizontal direction (i.e., the y-direction) and may be separated from one another in the second horizontal direction (i.e., the x-direction).

It is to be appreciated that the vertical depth of the recessed features 106 (as measured from the upper surface of the epitaxial layer 104 toward the substrate 102) may be configured such that there is full depletion of the epitaxial region 104 between the bottom of recessed features 106 (e.g., as shown in FIGS. 1 and 7) and the diffusion layer 105. Conversely, the vertical depth of the recessed features 106 may be configured to be shallower, such that a prescribed lower portion of the epitaxial layer 104—between the bottom of the recessed features 106 and the diffusion layer 105—is not fully depleted (e.g., as shown in FIG. 8). Thus, in the embodiments shown in FIG. 1, 7 or 8, the resistive layer (e.g., film) 110 may be configured to convey a current that fully (or mostly) depletes the region of the epitaxial layer 104 between adjacent recessed features 106, so as to form a charge balanced region in the semiconductor device.

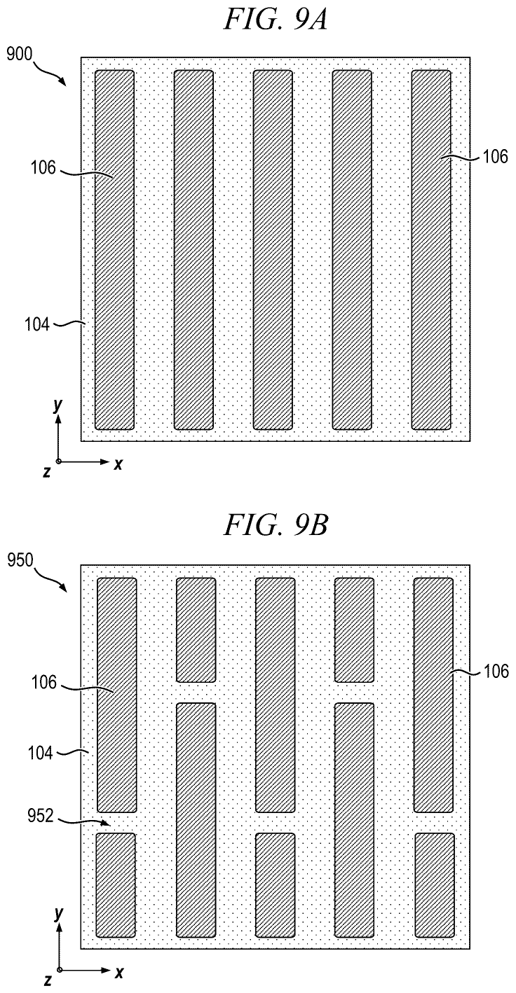

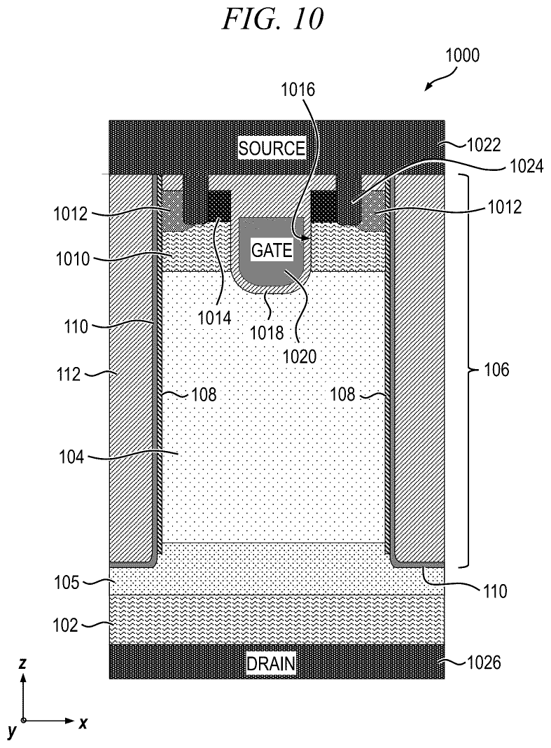

By way of example only and without limitation, FIGS. 9A and 9B are schematic top plan views depicting at least a portion of example semiconductor devices conceptually illustrating different configurations of the recessed features 106, according to embodiments of the inventive concept. Referring to FIG. 9A, a semiconductor device 900 includes a plurality of recessed features 106 configured in an end-to-end trench pattern. In this illustrative embodiment, each of the recessed features 106 may be formed as trenches extending continuously in the first horizontal direction (y-direction) from a first end of the epitaxial layer 104 to a second end of the epitaxial layer 104, opposite the first end. The recessed features 106 may be spaced apart from one another in the second horizontal direction (x-direction).

With reference to FIG. 9B, a semiconductor device 950 includes a plurality of recessed features 106 configured in an interrupted (i.e., discontinuous) trench pattern. Specifically, in this illustrative embodiment, each of at least a subset of the recessed features 106 may be formed as trenches extending longitudinally in the first horizontal direction (y-direction), but rather than extending continuously from one end of the epitaxial layer 104 to the other, each of at least a subset of the recessed features 106 may be configured as a discontinuous trench having one or more breaks (i.e., gaps) 952 separating portions of the recessed feature 106 from one another in the first horizontal direction. The breaks 952 may comprise portions of the epitaxial layer 104, or the breaks 952 may comprise a material different from the epitaxial layer 104 (e.g., silicon dioxide, air, etc.). The recessed features 106, like in the semiconductor device 900 shown in FIG. 9A, may be spaced apart from one another in the second horizontal direction (x-direction).

Although embodiments of the present invention has been described herein in the context of a diode device, aspects of the inventive concept can be used with other device type, such as, for example, power MOSFET devices. FIG. 10 is a schematic cross-sectional view depicting at least a portion of an illustrative power MOSFET device 1000 that incorporates enhanced charge balancing, according to one or more embodiments of the present invention. Referring to FIG. 10, the MOSFET device 1000 in this illustrative embodiment is configured as a vertical power MOSFET formed between adjacent recessed features 106. A body region 1010 may be formed in the epitaxial layer (i.e., drift region) 104 proximate the upper surface of the epitaxial layer 104. The body region 1010 may extend vertically (i.e., in the z-direction) partially into the epitaxial layer 104 (downwardly from the upper surface of the epitaxial layer 104) and may extend longitudinally (i.e., in the x-direction) between adjacent recessed features 106. The body region 1010 may extend substantially across an upper portion of the epitaxial layer 104 and contact the insulating layer 108 of each of the adjacent recessed features 106.

In one or more embodiments, the body region 1010 may be doped with an impurity having a doping type that is opposite that of the epitaxial layer 104. For example, for an N-type epitaxial layer 104, the body region 1010 may be doped with a P-type impurity of a prescribed doping concentration, and thus the body region 1010 may be referred to in this illustrative embodiment as a P-body region. The body region 1010 will ultimately form source regions of the vertical MOSFET device 1000.

A plurality of first wells (i.e., first implant regions) 1012 may be formed in the body region 1010 proximate an upper surface of the body region 1010. The first wells 1012 may be doped with an impurity having the same doping type as that of the body region 1010, such as by using an implantation process (e.g., ion implantation). Thus, for a P-body region 1010, the first wells 1012 may be P-type wells. A doping concentration of the first wells 1012 may be greater than the doping concentration of the body region 1010. The first wells 1012 may extend partially in the body region 101 in the vertical direction.

A plurality of second wells (i.e., second implant regions) 1014 may also be formed in the body region 1010 proximate the upper surface of the body region 1010. The second wells 1014 may be doped with an impurity having a doping type that is opposite that of the body region 1010, such as by using an implantation process (e.g., ion implantation). Thus, for a P-body region 1010, the second wells 1014 may be N-type wells. Each of the second wells 1014 may be laterally adjacent (i.e., in the x-direction) a corresponding one of the first wells 1012 and may extend partially in the body region 1010 in the vertical direction. Each pair of a corresponding first well 1012 and second well 1014 in a given P-body region 1010 will form a source contact of the MOSFET device 1000.

A trench 1016 is formed extending vertically from the upper surface of the epitaxial layer 104, through the body region 1010, and at least partially into the epitaxial layer 104. The trench 1016 extends between the first wells 1012 and the second wells 1014 and divides the body region 1010 into laterally separate portions on opposing sidewalls of the trench 1016. The trench 1016 can be formed, for example, using an etching process (e.g., anisotropic etching), although embodiments are not limited thereto. A dielectric layer 1018 may be formed on the sidewalls and bottom of the trench 1016. A gate electrode 1020 may be formed on the dielectric layer 1018 in the trench 1016. The gate electrode 1020 may extend longitudinally in the y-direction. The gate electrode 1020, which may comprise, for example, polysilicon or a metal, is isolated from direct electrical contact with the epitaxial layer 104, body region 1010 and second wells 1014 by the dielectric layer 1018. Accordingly, the dielectric layer 1018 serves as a gate dielectric of the MOSFET device 1000. The dielectric layer 1018 and the gate electrode 1020, together, form a trenched gate structure of the MOSFET device 1000.

In one or more embodiments, the dielectric layer 1018 may comprise an oxide, such as, for example, silicon dioxide, although embodiments are not limited thereto. The dielectric layer 1018 may be formed using an oxide growth or deposition process, although embodiments are not limited thereto. The dielectric layer 1018 may extend on an upper surface of the gate electrode 1020 and extend horizontally on an upper surface of each of the first wells 1012 and second wells 1014 between adjacent recessed features 106. Opposing ends of the dielectric layer 1018 may contact the insulating layer 108 of each of the adjacent recessed features 106. The dielectric layer 1018 may comprise the same material as the dielectric material 112 used to fill the recessed features 106. In one or more embodiments, the upper surface of the recessed features 106 may be coplanar with the upper surface of the dielectric layer 1018, relative to the upper surface of the substrate 102 as a reference layer.

The MOSFET device 1000 further includes a source contact or electrode 1022 extending in the horizontal direction (i.e., x-direction) on the upper surface of the adjacent recessed features 106 and on the upper surface of the dielectric layer 1018. Conductive posts or vias (i.e., conductive plug) 1024 may be formed extending through the dielectric layer 1018 and electrically connecting the first and second wells 1012, 1014 to the source electrode 1022. The source electrode 1022 is also electrically connected to the resistive layer 110 for providing a voltage potential configured to cause a current to be conveyed in the resistive layer 110 of each of the adjacent recessed features 106 for depleting the epitaxial layer 104 between the adjacent recessed features 106, as previously described in conjunction with FIGS. 2A-2D. In one or more embodiments, the source electrode 1022 comprises a metal (e.g., aluminum, copper, etc.) or metal silicide. The conductive post 1024 may be formed contiguously with the source electrode 1022, such as by using a metallization process. In some embodiments, the conductive posts 1022 may comprise tungsten, although embodiments are not limited thereto.

The MOSFET device 1000 further includes a drain contact or electrode 1026. The drain electrode 1026 may be formed on a back surface of at least a portion of the substrate 1026. The drain electrode 1026 provides an electrical connection with the substrate 102 which serves as a drain of the MOSFET device 1000. Like the source electrode 1022, the drain electrode 1026 may comprise a metal or metal silicide. The source and drain electrodes 1022, 1026 may be formed of the same material, although embodiments contemplate that the source and drain electrodes 1022, 1026 may comprise different materials. In one or more embodiments, a first adhesion layer (e.g., 116 in FIG. 1) may be provided on at least a portion of the upper surfaces of the insulating layer 108, the resistive layer 110, the dielectric material 112, the dielectric layer 1018, and the conductive post 1022. The first adhesion layer serves, at least in part, to facilitate enhanced adhesion between the source electrode 1022, provided on an upper surface of the first adhesion layer, and the underlying resistive layer 110 and the conductive post 1024. The first adhesion layer, which is electrically conductive, may be beneficial in a thick metal deposition process that may be used to form the source electrode 1022.

Similarly, a second adhesion layer (120 in FIG. 1) may be provided on a back surface of the substrate 102. In some embodiments, the second adhesion layer 120, which is electrically conductive, may comprise, for example, titanium (Ti), nickel (Ni) and/or silver (Ag) and serves, at least in part, to facilitate adhesion between the underlying substrate 102 and the drain electrode 1026 provided on a back surface of the second adhesion layer. The second adhesion layer may be beneficial in a thick metal deposition process that may be used to form the drain electrode 1026. The first and second adhesion layers may comprise the same material, although embodiments are not limited thereto.

Although the present disclosure provides several non-limiting examples of illustrative charge compensation structures for use in a charge balanced semiconductor device, various modifications and changes can be made thereto without departing from the scope of the disclosure as set forth in the claims below, as may become apparent to those skilled in the art given the teachings herein. Accordingly, the specification and figures are to be regarded in an illustrative rather than a restrictive sense, and all such modifications are intended to be included within the scope of the present inventive concept. Any benefits, advantages, or solutions to problems that are described herein with regard to a specific example are not intended to be construed as a critical, required, or essential feature or element of any or all of the claims.

Although the overall fabrication methods and the structures formed thereby are entirely novel, certain individual processing steps required to implement the methods described herein may utilize conventional semiconductor fabrication techniques and conventional semiconductor fabrication tooling. These techniques and tooling will already be familiar to those having ordinary skill in the relevant arts given the teachings herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are both hereby incorporated herein by reference in their entireties for all purposes. It is emphasized that while some individual processing steps are set forth herein, those steps are merely illustrative, and one skilled in the art may be familiar with several equally suitable alternatives that would also fall within the scope of the invention.

It is to be appreciated that the various layers and/or regions shown in the accompanying figures may not be drawn to scale. Furthermore, one or more semiconductor layers of a type commonly used in such semiconductor devices may not be explicitly shown in a given figure to facilitate enhanced clarity of the description. This does not imply that the semiconductor layer(s) not explicitly shown are omitted in the actual device.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent (i.e., dopant) has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations of the intrinsic semiconductor material at thermal equilibrium. Dominant carrier concentration in an extrinsic semiconductor material determines the conductivity type of the semiconductor material.

The term “metal,” as used herein, is intended to refer to any electrically conductive material, regardless of whether the material is technically defined as a metal from a chemistry perspective or not. Thus “metals” as used herein will include such materials as, for example, aluminum, copper, silver, gold, etc., and will include such materials as, for example, graphene, germanium, gallium arsenide, highly-doped polysilicon (commonly used in most MOSFET devices), etc. This is to be distinguished from the definition of a “metal” from a physics perspective, which usually refers to those elements having a partially filled conduction band and having lower resistance toward lower temperature.

As used herein, the term “insulating” may generally denote a material having a room temperature conductivity of less than about 10⁻¹⁰ (Ω-m)⁻¹. Suitable insulating materials may include, but are not limited to, silicon oxide, silicon nitride, silicon oxynitride, boron nitride, high-dielectric constant (high-k) materials, or any combination of these materials. Non-limiting examples of high-k materials may include, for example, metal oxides, such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate, ceramics, etc. High-k materials may further include dopants such as lanthanum, aluminum, etc.

As used herein, “P-type” may refer broadly to the addition of impurities to an intrinsic semiconductor material that creates deficiencies of valence electrons. In a silicon-containing material, non-limiting examples of P-type dopants (i.e., impurities) include boron, aluminum, gallium and indium.

As used herein, “N-type” may refer broadly to the addition of impurities that contribute free electrons to an intrinsic semiconductor material. In a silicon-containing material, non-limiting examples of N-type dopants include antimony, arsenic and phosphorous.

In the description above, each example embodiment may be described as having a certain conductivity type. It will be appreciated, however, that opposite conductivity type devices may be formed by simply reversing the conductivity of the N-type and P-type layers in each of the above embodiments. Thus, it will be understood that the present invention covers both N-type and P-type devices for each different device structure (e.g., Schottky diode, MOSFET, IGBT, etc.).

For reference purposes only, ordinal terms such as, for example, “first,” “second,” and similar terms, as may be used herein, are not intended to be limiting. Unless the context clearly indicates otherwise, the terms “first,” “second,” and other such words involving structures or elements are generally intended to distinguish one structure or element from another structure or element and are not intended to imply a particular sequence or order.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Furthermore, positional (i.e., directional) terms such as “above,” “below,” “upper,” “lower,” “under,” and “over” as may be used herein, are intended to indicate relative positioning of elements or structures to each other as opposed to absolute position.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having charge compensation structures therein (e.g., power IC devices) formed in accordance with one or more embodiments of the invention.

An integrated circuit formed in accordance with aspects of the present disclosure can be employed in essentially any application and/or electronic system involving enhanced breakdown voltage structures, such as, but not limited to, power metal-oxide semiconductor field-effect transistors (MOSFETs), Schottky diodes, etc. Suitable systems and applications for implementing embodiments of the invention may include, but are not limited to, AC-DC and DC-DC conversion, motor control, and power supply OR-ing (“OR-ing” is a particular type of application that parallels multiple power supplies to one common power bus in a redundant power system architecture). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the structures and semiconductor fabrication methodologies described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not necessarily drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus, the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

1. A method for forming a charge balance region in a semiconductor device, the method comprising:
providing an epitaxial layer on an upper surface of a substrate of the semiconductor device, whereby a diffusion layer is formed between the substrate and the epitaxial layer, the diffusion layer being a transition region between the substrate, having a first doping concentration, and the epitaxial layer, having a second doping concentration that is lower than the first doping concentration;
forming a plurality of recessed features extending in a first direction, perpendicular to the upper surface of the substrate, at least partially into the epitaxial layer and spaced apart from one another in a second direction parallel to the upper surface of the substrate;
forming an insulating layer on at least sidewalls of each of the plurality of recessed features; and
forming a resistive film on at least a portion of the insulating layer and a bottom of each of the plurality of recessed features using atomic layer deposition,
wherein the resistive film is configured to provide a conductive path between an upper surface of the epitaxial layer and one of the diffusion layer, a lower portion of the epitaxial layer, or the substrate, whereby a current flowing through the resistive film fully depletes at least a portion of the epitaxial layer between adjacent recessed features.

2. The method according to claim 1, wherein forming the plurality of recessed features comprises forming deep, high aspect ratio trenches extending in the first direction at least partially into the epitaxial layer.

3. (canceled)

4. The method according to claim 1, wherein forming the insulating layer comprises at least one of depositing, using atomic layer deposition, or thermally growing an electrically insulating material to conformally cover the sidewalls and bottom of each of the plurality of recessed features.

5. The method according to claim 1, wherein forming the resistive film comprises:
removing the insulating layer on the bottom of each of the plurality of recessed features to expose the diffusion layer, the epitaxial layer, or the substrate; and
depositing, using atomic layer deposition, the resistive film to conformally cover the sidewalls and bottom of each of the plurality of recessed features.

6. The method according to claim 1, wherein forming the resistive film comprises:
exposing the diffusion layer, the epitaxial layer, or the substrate through the bottom of each of the plurality of recessed features;
depositing, using atomic layer deposition, an electrically insulating material on the sidewalls and bottom of each of the plurality of recessed features; and
performing thermal processing, whereby the electrically insulating material is converted to the resistive film having electrically conductive properties.

7. The method according to claim 6, wherein forming the resistive film further comprises controlling a resistivity of the resistive film by controlling a temperature and/or a duration of the thermal processing.

8. (canceled)

9. The method according to claim 1, wherein forming the resistive film comprises:
depositing, using atomic layer deposition, a first layer of electrically insulating material on the sidewalls and bottom of each of the plurality of recessed features such that the first layer of electrically insulating material on the bottom of each of the plurality of recessed features electrically contacts the diffusion layer, the epitaxial layer, or the substrate;
depositing, using atomic layer deposition, a second layer of electrically insulating material on the first layer of electrically insulating material in each of the plurality of recessed features; and
performing thermal processing, whereby the first and second layers of electrically insulating material combine to form the resistive film having electrically conductive properties.

10. The method according to claim 9, wherein the first layer of electrically insulating material comprises aluminum oxide (Al₂O₃) and the second layer of electrically insulating material comprises molybdenum trioxide (MoO₃), and wherein the resistive film comprises an Al₂O₃—MoO₃ compound.

11. (canceled)

12. The method of claim 1, wherein forming the resistive film comprises:
providing a charge prevention layer on the sidewalls of each of the plurality of recessed features and on the upper surface of the epitaxial layer between adjacent recessed features;
exposing the diffusion layer, the epitaxial layer, or the substrate through the bottom of each of the plurality of recessed features; and
depositing, using atomic layer deposition, the resistive film on the charge prevention layer and on the bottom of the recessed features.

13. The method according to claim 12, further comprising:
performing thermal processing; and
at least partially filling each of the plurality of recessed features with a dielectric fill material, an upper surface of the dielectric fill material being substantially coplanar with the upper surface of the epitaxial layer.

14. (canceled)

15. The method according to claim 1, wherein forming each of at least a subset of the plurality of recessed features comprises forming a trench extending longitudinally in a third direction parallel to the upper surface of the substrate and intersecting the second direction, the trench having one or more breaks separating portions of the recessed feature from one another in the third direction.

16. The method according to claim 1, wherein forming each of at least a subset of the plurality of recessed features comprises forming a continuous trench extending longitudinally in a third direction, parallel to the upper surface of the substrate and intersecting the second direction, from one end of the epitaxial layer to an opposite end of the epitaxial layer.

17. The method according to claim 1, wherein the semiconductor device comprises a Schottky diode, the method further comprising:
at least partially filling each of the recessed features with a fill material, an upper surface of the fill material being substantially coplanar with the upper surface of the epitaxial layer;
forming a Schottky contact in the epitaxial layer proximate the upper surface of the epitaxial layer;
forming a first metal contact on an upper surface of the Schottky contact and extending in the second direction, the first metal contact serving as an anode of the Schottky diode; and
forming a second metal contact on a back surface of the substrate and extending in the second direction, the second metal contact serving as a cathode of the Schottky diode.

18. (canceled)

19. The method according to claim 17, further comprising:
forming an electrically conductive first adhesion layer between the Schottky contact and the first metal contact; and
forming an electrically conductive second adhesion layer between the substrate and the second metal contact.

20. The method according to claim 1, wherein the semiconductor device comprises a metal-oxide-semiconductor field-effect transistor (MOSFET), the method further comprising:
at least partially filling each of the recessed features with a fill material, an upper surface of the fill material being substantially coplanar with the upper surface of the epitaxial layer;
forming a body region in the epitaxial layer proximate the upper surface of the epitaxial layer and between adjacent recessed features in the second direction, the body region extending partially in the epitaxial layer in the first direction, the body region having a first conductivity type and the epitaxial layer having a second conductivity type;
forming a plurality of first wells in the body region proximate an upper surface of the body region and extending partially in the body region in the first direction, the first wells having the first conductivity type;
forming a plurality of second wells in the body region proximate the upper surface of the body region and extending partially in the body region in the first direction, the second wells being adjacent the first wells in the second direction and having the second conductivity type;
forming a trenched gate structure extending in the first direction from the upper surface of the body region, through the body region and into the epitaxial layer, the trenched gate structure being disposed between adjacent second wells in the second direction;
forming a source electrode on an upper surface of the recessed features and electrically connected to the body region and the resistive film; and
forming a drain electrode on a back surface of the substrate and electrically connected to the substrate.

21. The method according to claim 20, wherein forming a trenched gate structure comprises:
forming a dielectric layer conformally on sidewalls and a bottom of a trench formed in the body region; and
forming a gate electrode on the dielectric layer.

22. A semiconductor device, comprising:
a semiconductor substrate;
a diffusion layer on an upper surface of the substrate, the diffusion layer having a first doping concentration;
an epitaxial layer on an upper surface of the diffusion layer, the epitaxial layer having a second doping concentration that is less than the first doping concentration;
a plurality of recessed features extending in a first direction, perpendicular to the upper surface of the substrate, at least partially into the epitaxial layer and extending longitudinally in a second direction parallel to the upper surface of the substrate, the recessed features being spaced apart from one another in a third direction parallel to the upper surface of the substrate and intersecting the second direction;
an insulating layer on at least sidewalls of each of the plurality of recessed features; and
a resistive film on at least a portion of the insulating layer and a bottom of each of the plurality of recessed features, the insulating layer being disposed between the resistive film and the epitaxial layer,
wherein the resistive film is configured to provide a conductive path between an upper surface of the epitaxial layer and the diffusion layer or a lower portion of the epitaxial layer, whereby a current flowing through the resistive film fully depletes at least a portion of the epitaxial layer between adjacent recessed features to form a charge balance region in the semiconductor device.

23. The semiconductor device according to claim 22, wherein the plurality of recessed features extends in the first direction through the epitaxial layer and at least partially into the diffusion layer.

24. The semiconductor device according to claim 22, wherein the plurality of recessed features extends in the first direction through the epitaxial layer and the diffusion layer, and at least partially into the substrate.

25. (canceled)

26. The semiconductor device according to claim 22, wherein a resistivity of the resistive film is configured as a function of a temperature and duration of thermal processing of the semiconductor device.

27. The semiconductor device according to claim 22, further comprising a dielectric material at least partially filling each of at least a subset of the recessed features, an upper surface of the dielectric material being substantially coplanar with the upper surface of the epitaxial layer.

28. The semiconductor device according to claim 22, wherein the resistive film comprises a first layer of electrically insulating material and a second layer of insulating material on the first layer of electrically insulating material, wherein the first and second layers of electrically insulating material, through thermal processing, are combined to form the resistive film having electrically conductive properties.

29. The semiconductor device according to claim 22, wherein the resistive film is a multilayer composite structure comprising aluminum oxide (Al₂O₃) and molybdenum trioxide (MoO₃).

30. The semiconductor device according to claim 22, wherein a resistivity of the resistive film is in a range of about 10⁶ ohms-centimeter (Ω-cm) to about 10¹² Ω-cm.

31. The semiconductor device according to claim 22, further comprising a charge prevention layer on the sidewalls of each of the plurality of recessed features and on the upper surface of the epitaxial layer between adjacent recessed features, the charge prevention layer being disposed between the insulating layer and the resistive film.

32. The semiconductor device according to claim 31, wherein the charge prevention layer comprises hafnium oxide (HfO₂).

33. The semiconductor device according to claim 22, wherein each of at least a subset of the plurality of recessed features comprises a discontinuous trench extending longitudinally in the second direction, the trench having one or more breaks separating portions of the recessed feature in the second direction.

34. The semiconductor device according to claim 22, wherein the semiconductor device comprises a Schottky diode, the Schottky diode further comprising:
a fill material at least partially filling each of the recessed features, an upper surface of the fill material being substantially coplanar with the upper surface of the epitaxial layer;
a Schottky contact in the epitaxial layer proximate the upper surface of the epitaxial layer;
an anode electrode on an upper surface of the Schottky contact and extending in the second direction, the anode electrode being electrically connected to the Schottky contact; and
a cathode electrode on a back surface of the substrate and extending in the second direction, the cathode electrode being electrically connected to the substrate.

35. The semiconductor device according to claim 22, wherein the semiconductor device comprises a metal-oxide-semiconductor field-effect transistor (MOSFET), the MOSFET further comprising:
a body region in the epitaxial layer proximate the upper surface of the epitaxial layer and between adjacent recessed features in the second direction, the body region extending partially in the epitaxial layer in the first direction, the body region having a first conductivity type and the epitaxial layer having a second conductivity type;
a plurality of first wells in the body region proximate an upper surface of the body region and extending partially in the body region in the first direction, the first wells having the first conductivity type;
a plurality of second wells in the body region proximate the upper surface of the body region and extending partially in the body region in the first direction, the second wells being adjacent the first wells in the second direction and having the second conductivity type;
a trenched gate structure extending in the first direction from the upper surface of the body region, through the body region and into the epitaxial layer, the trenched gate structure being between adjacent second wells in the second direction;
a source electrode on an upper surface of the recessed features and electrically connected to the body region and the resistive film; and
a drain electrode on a back surface of the substrate and electrically connected to the substrate.

36. (canceled)
